(19) United States
(12) Patent Application Publication
(10) Pub. No.: US 2025/0331258 A1
(43) Pub. Date: Oct. 23, 2025

(54) SEMICONDUCTOR STRUCTURE WITH REDUCED CURRENT LEAKAGE AND METHOD FOR MANUFACTURING THE SAME

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/639,105

(22) Filed: Apr. 18, 2024

(51) Int. Cl. H01L 29/10; H01L 21/8238; H01L 27/092; H01L 29/06; H01L 29/08; H01L 29/423; H01L 29/66; H01L 29/775; H01L 29/786

(52) U.S. Cl. CPC H10D 62/371; H10D 30/014; H10D 30/43; H10D 30/6735; H10D 30/6757; H10D 62/115; H10D 62/121; H10D 62/151; H10D 64/017; H10D 84/0167; H10D 84/017; H10D 84/0186; H10D 84/0188; H10D 84/0191; H10D 84/038; H10D 84/85

(57) ABSTRACT

A semiconductor structure includes a first well and a second well which has a conductivity type opposite to that of the first well; a first semiconductor device formed on the first well and including a first channel, two first source/drain portions which have a conductivity type opposite to that of the first well, and at least one first isolation feature including a first doped-semiconductor portion and a first insulating portion, a conductivity type of the first doped-semiconductor portion being the same as that of the first source/drain portions; and a second semiconductor device formed on the second well and including a second channel, two second source/drain portions which have a conductivity type opposite to that of the second well, and at least one second isolation feature including a second insulating portion disposed to separate the second well from a corresponding one of the second source/drain portions.

### BACKGROUND

Nowadays, integrated circuits (ICs) are used in consumer electronics products and automotive electronics products. Transistors are key active components in modern ICs. In order to manufacture electronics products with relatively lower power consumption, longer service lifetime, higher computing speed, and so on, many approaches are being continuously developed for optimizing each of the transistors in the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view illustrating a layout of a semiconductor structure in accordance with some embodiments.

FIGS. 2A, 2B, 2C and 2D are schematic sectional views of a first semiconductor structure which are respectively taken long line C1-C1′, line C2-C2′, line C3-C3′ and line C4-C4′ of FIG. 1 in accordance with some embodiments.

FIGS. 3A, 3B and 3C are schematic sectional views of a second semiconductor structure which are respectively taken long line C1-C1′, line C2-C2′, and line C3-C3′ of FIG. 1 in accordance with some other embodiments.

FIGS. 4A, 4B and 4C are schematic sectional views of a third semiconductor structure which are respectively taken long line C1-C1′, line C2-C2′, and line C3-C3′ of FIG. 1 in accordance with some other embodiments.

FIG. 5 is a flow diagram illustrating a method for manufacturing a semiconductor structure in accordance with some embodiments.

FIGS. 6 to 21C illustrate schematic views of intermediate stages of the method depicted in FIG. 5 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In advanced technology nodes of semiconductor fabrication, gate-all-around (GAA) field-effect transistors are advantageous because of better gate control ability thereof, which is beneficial in applications requiring low supply voltage in comparison with fin-type field-effect transistors (FinFETs). In a GAA field-effect transistor, although each channel is surrounded and controlled by a gate electrode, an off-state current leakage (Isoff) may present at an upper portion of a substrate which is located between the two source/drain portions and which is beneath the gate electrode but is not surrounded by the gate electrode. In addition, in a short-channel device where a gate length of the gate electrode is small, an anti-punch through (APT) implantation region may be formed in the substrate between the two source/drain portions so as to prevent a source-to-drain leakage. The present disclosure is directed to an isolation structure including a p-n junction located beneath each source/drain portion for reducing a source-to-well leakage or a drain-to-well leakage. With the provision of the isolation structure, the doping concentration of the APT implantation region may be reduced, or even the APT implantation region may be omitted, thereby avoiding a band-to-band tunneling (BTBT) effect-dominated p-n junction leakage which tends to occur at a heavily-doped p-n junction (e.g., a junction formed at an interface between each of the two source/drain portion and the APT implantation region).

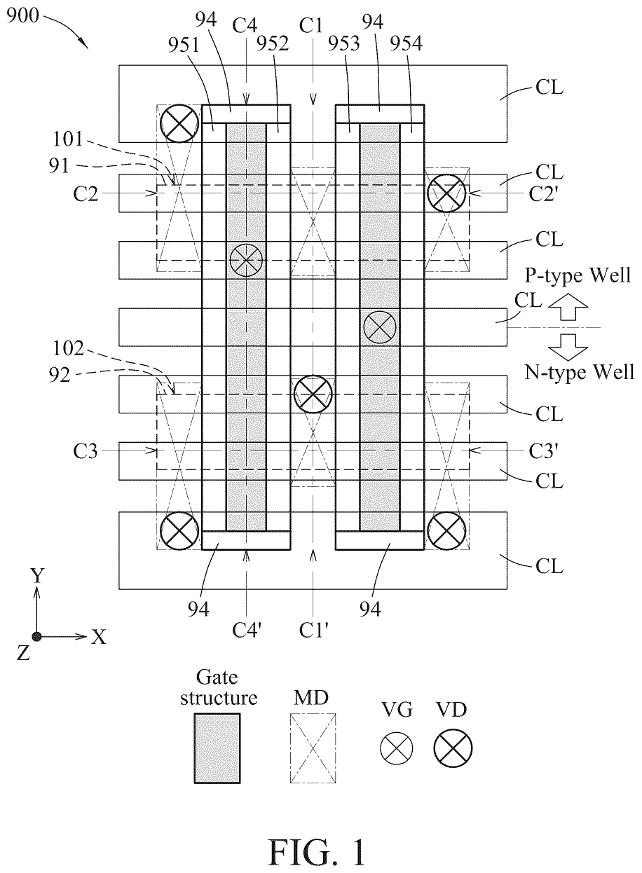

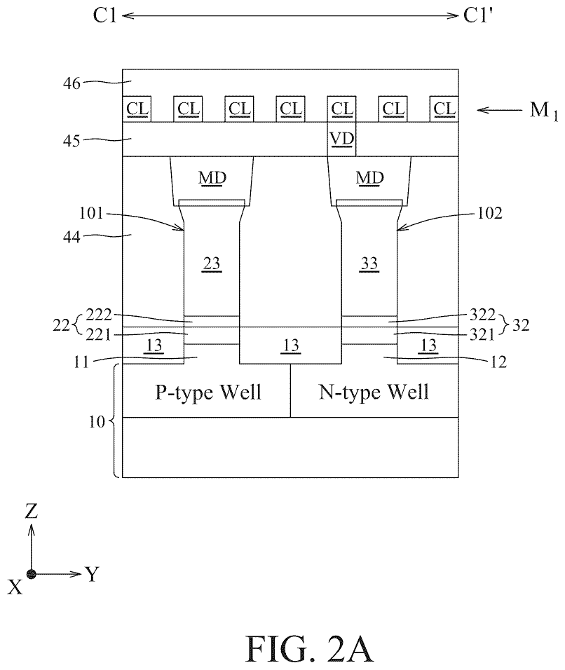

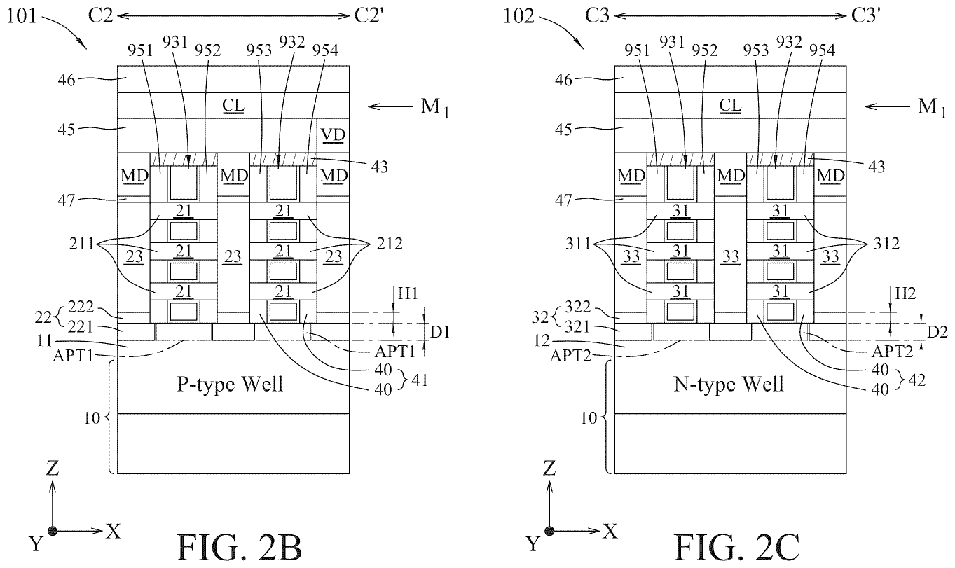

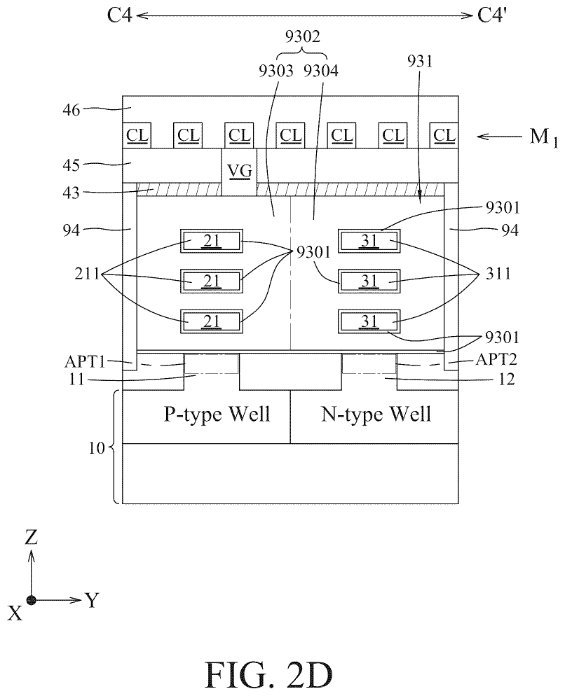

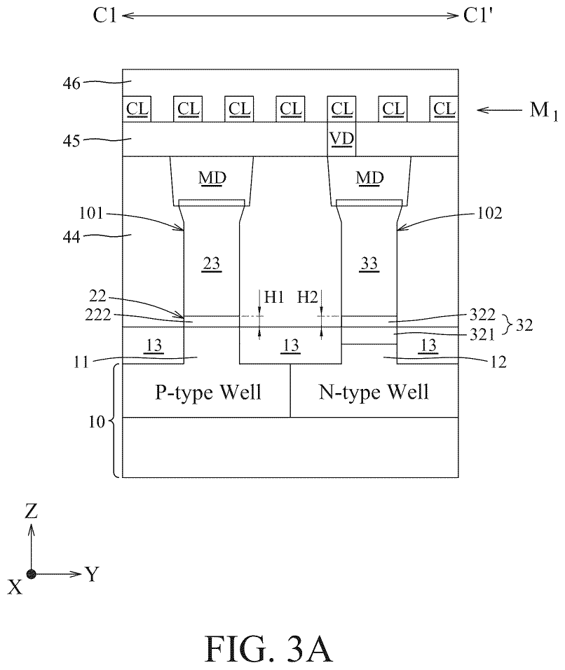

FIG. 1 is a schematic top view illustrating a layout 900 of a semiconductor structure in accordance with some embodiments. The layout 900 includes a p-type well, an n-type well, a plurality of active regions 91, 92, a plurality of gate structures, a plurality of cut-metal dielectric portions 94, a plurality of spacers 951, 952, 953, 954, a plurality of contact area (MD), a plurality of via contacts (VD), a plurality of gate contacts (VG), and a plurality of conductive lines (CL) located at M1 level (see also FIG. 2A).

The p-type well and the n-type well are displaced from each other, for example, but not limited to, in a Y direction. In some embodiments, the p-type well is for forming an n-type semiconductor device 101 thereon, and the n-type well is for forming a p-type semiconductor device 102 thereon. In some embodiments, the n-type semiconductor device 101 may include a plurality of n-type metal-oxide-semiconductor field-effect transistors (n-MOSFETs), and the p-type semiconductor device 102 may include a plurality of p-type metal-oxide-semiconductor field-effect transistors (p-MOSFETs).

The active regions 91, 92 are elongated in an X direction transverse to the Y direction and spaced apart from each other in the Y direction. In some embodiments, the active regions 91, 92 may be referred to as oxide-definition (OD) regions. In some embodiments, the active regions 91, 92 are isolated from each other by an isolation structure (not shown in FIG. 1). In some embodiments, the isolation structure may include, for example, but not limited to, a trench isolation, an inter-layer dielectric, etc. In some embodiments, as shown in FIG. 1, the active region 91 is located within the p-type well, and the active region 92 is located within the n-type well. That is, the active region 91 includes a part of the p-type well and includes p-type dopants of the p-type well, and the active region 92 includes a part of n-type well and includes n-type dopants of the n-type well. The n-type semiconductor device 101 and the p-type semiconductor device 102 are respectively disposed on the active region 91.

The gate structures are spaced apart from each other in the X direction and elongated in the Y direction. In some embodiments, a combination of the gate structures may be divided into two halves, one of which is formed on the active region 91 to control n-channels (not shown in FIG. 1) in the n-type semiconductor device 101, and the other one of which is formed on the active region 92 to control p-channels (not shown in FIG. 1) in the p-type semiconductor device 102. The details of the gate structures are described as follow. In some embodiments, each of the gate structures has two ends each of which is in contact with a corresponding one of the cut-metal dielectric portions 94.

The spacers 951, 952, 953, 954 are spaced apart from each other and elongated in the Y direction. Each of the spacers 951, 952, 953, 954 is disposed aside a corresponding one of the gate structures so as to isolate the corresponding gate structure from an adjacent conductive element. In some embodiments, the spacers 951, 952 are respectively disposed at two opposite sides of a left one of the gate structures in the X direction, and the spacers 953, 954 are respectively disposed at two opposite sides of a right one of the gate structures in the X direction.

Each of the contact areas (MD) is formed over a corresponding one of the active regions 91, 92. In some embodiments, three of the contact areas (MD) are formed over the first active region 91 and are respectively connected to n-type source/drain portions (not shown in FIG. 1) of the n-type semiconductor device 101. In some embodiment, another three of the contacts areas (MD) are formed over the active region 92 and are respectively connected to p-type source/drain portions (not shown in FIG. 1) of the p-type semiconductor device 102. Each of the contact areas (MD) is isolated from a corresponding adjacent one of the gate structures by a corresponding one of the gate spacers 951, 952, 953, 954.

Each of the via contacts (VD) is formed on and connected to a corresponding one of the contact areas (MD). Each of the gate contacts (VG) is formed on and connected to a gate electrode (not shown in FIG. 1) of a corresponding one of the gate structures.

In some embodiments, the conductive lines (CL) are elongated in the X direction and spaced apart from each other in the Y direction. Each of the conductive lines (CL) is formed on and connected to corresponding one(s) of the via contacts (VD) and the gate contacts (VG).

FIGS. 2A, 2B, 2C and 2D are schematic sectional views of a first semiconductor structure which are respectively taken long line C1-C1′, line C2-C2′, line C3-C3′ and line C4-C4′ of FIG. 1 for further illustrating elements that are omitted in FIG. 1 in accordance with some embodiments. Each of the n-type semiconductor device 101 and the p-type semiconductor device 102 in the first semiconductor structure that is exemplarily shown in FIGS. 2A, 2B, 2C, and 2D has a horizontal gate-all-around (GAA) structure. That is, the source/drains portions of each of the devices 101, 102 are located at the same level. In some other embodiments not shown herein, each of the n-type semiconductor device 101 and the p-type semiconductor device 102 may have a complementary field-effect transistor (CFET) structure which includes two horizontal GAAFETs stacked on one another in a Z direction transverse to the X and Y directions, a fork-sheet structure which includes two horizontal GAAFETs spaced part from each other in the Y direction through a wall portion, or other suitable three-dimensional (3d) transistors (e.g., a vertical GAA structure in which the source/drains portions in each of the devices may be at different levels).

In addition to the elements shown in FIG. 1, the first semiconductor structure includes a substrate 10, first and second semiconductor fins 11, 12, trench isolations 13, two stacks 211, 212 of n-channels 21, three first isolation features 22, three n-type source/drain portions 23, two stacks 311, 312 of p-channels 31, three second isolation features 32, three p-type source/drain portions 33, first dielectric units 41, and second dielectric units 42.

The semiconductor fins 11, 12 are formed on the substrate 10 to respective serve as the active regions 91, 92 shown in FIG. 1. Each of the trench isolations 13 is formed to separate two adjacent ones of the semiconductor fins 11, 12. The three first isolation features 22 are formed in the n-type semiconductor device 101 and disposed on the first semiconductor fin 11. The three n-type source/drain portions 23 are formed in the n-type semiconductor device 101 and respectively disposed on the three first isolation features 22. The two stacks 211, 212 of n-channels 21 are formed in the n-type semiconductor device 101 and stacked over the first semiconductor fin 11 such that each stack 211, 212 of the n-channels 21 extends between two adjacent ones of the n-type source/drain portions 23. The three second isolation features 32 are formed in the p-type semiconductor device 102 and disposed on the second semiconductor fin 12. The three p-type source/drain portions 33 are formed in the p-type semiconductor device 102 and respectively disposed on the three second isolation features 32. The two stacks 311, 312 of p-channels 31 are formed in the p-type semiconductor device 102 and stacked over the second semiconductor fin 12 such that each stack 311, 312 of the p-channels 31 extends between two adjacent ones of the p-type source/drain portions 33. Each of the first dielectric units 41 is formed beneath a corresponding one of the n-channels 21 in the stacks 211, 212, and each of the second dielectric units 42 is formed beneath a corresponding one of the p-channels 31 in the stacks 311, 312. Each of the dielectric units 41, 42 includes two inner spacers 40.

The gate structures shown in FIGS. 2B to 2D are denoted by 931 and 932, respectively. The gate structure 931 is formed around the stack 211 of the n-channels 21 and the stack 311 of the p-channels 31. The gate structure 932 is formed around the stack 212 of the n-channels 21 and the stack 312 of the p-channels 31. The contact areas (MD) are respectively formed on the n-type source/drain portions 23 and the p-type source/drain portions 33. Each of the spacers 951, 952, 953, 954 is disposed to separate one of the gate structures 931, 932 from a corresponding adjacent one of the contact areas (MD).

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 10 may be configured as a semiconductor-on-insulator substrate. Other suitable materials and configurations for the substrate 10 are within the contemplated scope of the present disclosure.

In some embodiments, each of the semiconductor fins 11, 12 includes a semiconductor material (such as the examples of the semiconductor material for forming the substrate 10). As shown in FIGS. 2A to 2D, the p-type well is formed at the first semiconductor fin 11 and a first upper portion of the substrate 10 which is immediately beneath the first semiconductor fin 11, and the n-type well is formed at the second semiconductor fin 12 and a second upper portion of the substrate 10 which is immediately beneath the second semiconductor fin 12. Each of the first semiconductor fin 11 and the first upper portion of the substrate 10 may include p-type dopants to have a p-type conductivity, and each of the second semiconductor fin 12 and the second upper portion of the substrate 10 may include n-type dopants to have an n-type conductivity. In some embodiments, a doping concentration of the p-type dopants in the first semiconductor fin 11 (i.e., a doping concentration of the p-type well) may range from about 1E15 atoms/cm³ to about 1E18 atoms/cm³. In some embodiments, a doping concentration of the n-type dopants in the second semiconductor fin 12 (i.e., a doping concentration of the n-type well) may range from about 1E15 atoms/cm³ to about 1E18 atoms/cm³. In some embodiments, each of the first semiconductor fin 11 and the first upper portion of the substrate 10 may be made of a group IV semiconductor material, and the p-type dopants doped in the group IV semiconductor material may include group III elements, such as boron or boron compound (for example, B, ¹¹B, BF₂), aluminum (Al), indium (In), gallium (Ga), or combinations thereof. In some embodiments, each of the second semiconductor fin 12 and the second upper portion of the substrate 10 may be made of a group IV semiconductor material, and the n-type dopants doped in the group IV semiconductor material may include group V elements, such as phosphorous (P, 31P), arsenic (As), antimony (Sb), or combinations thereof.

In some embodiments, the trench isolations 13 may each be a shallow trench isolation (STI), a deep trench isolation (DTI), or other suitable structures. In some embodiments, the trench isolations 13 may include silicon oxide, silicon nitride, silicon oxynitride, or combinations thereof. Other insulating materials suitable for the isolation portions 13 are within the contemplated scope of the present disclosure.

In some embodiments, the n-channels 21 in each stack 211, 212 are spaced apart from each other and each includes a semiconductor material (such as the examples of the semiconductor material for forming the substrate 10). In some embodiments, the p-channels 31 in each stack 311, 312 are spaced apart from each other and each includes a semiconductor material (such as the examples of the semiconductor material for forming the substrate 10). The semiconductor material of the n-channels 21 may be the same as or different from the semiconductor material of the p-channels 31. In some embodiments, a number of the n-channels 21 or the p-channels 31 in each stack 211, 212, 311, 312 is in a range of about 2 to about 10, or about 2 to about 4. The number of the n-channels 21 in each stack 211, 212 may be the same or different from that of the p-channels 31 in each stack 311, 312. A thickness (value 1) of each of the n-channels 21 and the p-channels 31 in the Z direction ranges from about 3 nm to about 9 nm. A spacing (value 2) between two adjacent ones of the n-channels 21 or the p-channels 31 in each stack 211, 212, 311, 312 in the Z direction ranges from about 4 nm to about 14 nm. A pitch (a sum of values 1 and 2) of the n-channels 21 or the p-channels 31 in each stack 211, 212, 311, 312 ranges from about 7 nm to about 23 nm.

In some embodiments, each of the n-type source/drain portions 23 and the p-type source/drain portions 33 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. Each of the n-type source/drain portions 23 is doped with n-type dopants so as to function as a source or a drain of an n-MOSFET. The n-type dopants may be, for example, but not limited to, nitrogen (N), phosphorous (P), arsenic (As), antimony (Sb), other suitable materials, or combinations thereof. In some embodiments, a doping concentration of the n-type dopants in each of the n-type source/drain portions 23 may range from about 2E19 atoms/cm³ to about 1E22 atoms/cm³. In some embodiments, a phosphorous concentration in each of the n-type source/drain portions 23 ranges from about 2E19 atoms/cm³ to about 3E21 atoms/cm³. Each of the p-type source/drain portions 33 is doped with p-type dopants so as to function as a source or a drain of a p-MOSFET. The p-type dopants may be, for example, but not limited to, boron or boron compound (for example, B, ¹¹B, BF₂), aluminum (Al), gallium (Ga), indium (In), other suitable p-type dopants, or combinations thereof. In some embodiments, a doping concentration of the p-type dopants in each of the p-type source/drain portions 33 may range from about 1E19 atoms/cm³ to about 6E20 atoms/cm³. In some embodiments, a boron concentration in each of the p-type source/drain portions 33 ranges from about 1E19 atoms/cm³ to about 6E20 atoms/cm³.

In some embodiments, as shown in FIGS. 2A and 2B, each of the first isolation features 22 includes a first doped semiconductor portion 221 and a first insulating portion 222 which are respectively in contact with the first semiconductor fin 11 (i.e., a portion of the p-type well) and a respective one of the n-type source/drain portions 23.

The first doped semiconductor portion 221 includes n-type dopants to have an n-type conductivity, and thus a p-n junction is formed at an interface between the first doped semiconductor portion 221 and the p-type well. In some embodiments, a doping concentration of the n-type dopants in the first doped semiconductor portion 221 is less than the doping concentration of the n-type dopants in each of the n-type source/drain portions 23 by at least two to four orders of magnitude. In some embodiments, a difference between the doping concentration of the n-type dopants in the first doped semiconductor portion 221 and the doping concentration of the p-type dopants in the p-type well is not greater than two orders of magnitude. In some embodiments, the doping concentration of the n-type dopants in the first doped semiconductor portion 221 may range from about 1E16 atoms/cm³ to about 1E19 atoms/cm³. In some embodiments, the first doped semiconductor portion 221 includes a group IV semiconductor material, and the n-type dopants doped in the group IV semiconductor material may include group V elements, such as phosphorous (P, ³¹P), arsenic (As), antimony (Sb), other suitable n-type dopants, or combinations thereof. In some embodiments, the first doped semiconductor portion 221 has a thickness (D1) ranging from about 3 nm to about 30 nm.

It is worth noting that, since the difference between the doping concentration of the n-type dopants in the first doped semiconductor portion 221 and the doping concentration of the p-type dopants in the p-type well is sufficiently small, a band-to-band tunneling (BTBT) effect-dominated p-n junction leakage may be prevented from occurring at the interface between the first doped semiconductor portion 221 and the p-type well. In other words, by adjusting the doping concentration of the n-type dopants in the first doped semiconductor portion 221 to be close to the doping concentration of the p-type dopants in the p-type well, the value of a reverse bias p-n junction leakage at the interface between the first doped semiconductor portion 221 and the p-type well may be significantly reduced.

The first insulating portion 222 is disposed to prevent the first doped semiconductor portion 221 from being in physical contact with the respective one of the n-type source/drain portions 23. Furthermore, the first insulating portion 222 is disposed to be not in physical contact with the n-channels 21. In some embodiments, the first insulating portion 222 is in contact with two corresponding adjacent bottommost ones of the first dielectric units 41. In some embodiments, an upper surface of the first insulating portion 222 is located at a level that is lower than a level of a lower surface of a bottommost one of the n-channels 21 in a corresponding adjacent one of the stacks 211, 212. In some embodiments, the first insulating portion 222 includes a silicon oxide (e.g., SiO₂) based dielectric material, a silicon oxycarbide (SiOC) based dielectric material, a silicon oxynitride (SiON) based dielectric material, a silicon nitride (e.g., Si₃N₄) based dielectric material, a silicon oxycarbonitride (SiOCN) based dielectric material, other suitable materials, or combinations thereof. In some embodiments, the first insulating portion 222 has a first dielectric thickness (H1) ranging from about 1 nm to about 20 nm or about 1.5 nm to about 10 nm, and may include a single dielectric layer or multiple dielectric layers.

In some embodiments, as shown in FIGS. 2A and 2C, each of the second isolation features 32 includes a second doped semiconductor portion 321 and a second insulating portion 322 which are respectively in contact with the second semiconductor fin 12 (i.e., a portion of the n-type well) and a respective one of the p-type source/drain portions 33.

The second doped semiconductor portion 321 includes p-type dopants to have a p-type conductivity, and thus a p-n junction is formed at an interface between the second doped semiconductor portion 321 and the n-type well. In some embodiments, a doping concentration of the p-type dopants in the second doped semiconductor portion 321 is less than the doping concentration of the p-type dopants in each of the p-type source/drain portions 33 by at least two to four orders of magnitude. In some embodiments, a difference between the doping concentration of the p-type dopants in the second doped semiconductor portion 321 and the doping concentration of the n-type dopants in the n-type well is not greater than two orders of magnitude. In some embodiments, the doping concentration of the p-type dopants in the first doped semiconductor portion 321 may range from about 1E16 atoms/cm³ to about 1E19 atoms/cm³. In some embodiments, the second doped semiconductor portion 321 includes a group IV semiconductor material, and the p-type dopants doped in the group IV semiconductor material may include group III elements, such as boron or boron compound (for example, B, ¹¹B, BF₂), aluminum (Al), gallium (Ga), indium (In), other suitable p-type dopants, or combinations thereof. In some embodiments, the second doped semiconductor portion 321 has a thickness (D2) ranging from about 3 nm to about 30 nm.

The second insulating portion 322 is disposed to prevent the second doped semiconductor portion 321 from being in physical contact with the respective one of the p-type source/drain portions 33. Furthermore, the second insulating portion 322 is disposed to be not in physical contact with the p-channels 31. In some embodiments, the second insulating portion 322 is in contact with two corresponding adjacent bottommost ones of the second dielectric units 42. In some embodiments, an upper surface of the second insulating portion 322 is located at a level that is lower than a lower surface of a bottommost one of the p-channels 31 in a corresponding adjacent one of the stacks 311, 312. In some embodiments, the second insulating portion 322 includes a silicon oxide (e.g., SiO₂) based dielectric material, a silicon oxycarbide (SiOC) based dielectric material, a silicon oxynitride (SiON) based dielectric material, a silicon nitride (e.g., Si₃N₄) based dielectric material, a silicon oxycarbonitride (SiOCN) based dielectric material, other suitable materials, or combinations thereof. In some embodiments, the second insulating portion 322 has a second dielectric thickness (H2) ranging from about 1 nm to about 20 nm or about 1.5 nm to about 10 nm, and may include a single dielectric layer or multiple dielectric layers.

In some embodiments, each of the gate structures 931, 932 includes a gate dielectric 9301 and a gate electrode 9302. In some embodiments, the gate electrode 9302 includes a first gate region 9303 extending around the n-channels 21 and a second gate region 9304 extending around the p-channels 31. The gate electrode 9302 is separated from the n-channels 21 and the p-channels 31 by the gate dielectric 9301. The first gate region 9303 may include a work function metal material that is the same as or different from that of the second gate region 9304. In some embodiments, the gate dielectric 9301 includes a nitrogen doped oxide dielectric layer (i.e., an initial layer) combined with a metal-containing high-k dielectric layer (which has a dielectric constant is not less than about 9 or larger than about 13). The dielectric constant of the gate dielectric 9301 is greater than a dielectric constant of each of the first insulating portion 222 and the second isolating portion 322. The thickness of the metal-containing high-k dielectric layer is in a range from about 0.5 nm to about 3 nm. The metal-containing high-k dielectric layer includes, for example, but not limited to, Hf-containing dielectric oxide materials, Ta-containing dielectric oxide materials (e.g., Ta₂O₅), Ti-containing dielectric oxide materials, Zr-containing dielectric oxide materials, Al-containing dielectric oxide materials (e.g., Al₂O₃), La-containing dielectric materials, other suitable materials (having a dielectric constant not less than about 9 or larger than about 13), or combinations thereof. The materials (e.g. an electrically conductive material and the work function metal material) of the gate electrode 9302 may include, for example, but not limited to, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), or the like, or combinations thereof. Other suitable materials for forming the gate dielectric 9301 and the gate electrode 9302 are within the contemplated scope of the present disclosure.

In some embodiments, each of the spacers 951, 952, 953, 954 may be a single layer structure or a multiple layer structure, and may include, for example, but not limited to, a silicon oxide (e.g., SiO₂) based dielectric material, a silicon nitride (e.g., Si₃N₄) based dielectric material, a carbon-doped oxide material, a nitride-doped oxide material, a porous oxide material, other suitable materials, or combinations thereof. Other suitable materials for the spacers 951, 952, 953, 954 are within the contemplated scope of the present disclosure. In some embodiments, each of the spacers 951, 952, 953, 954 has a first spacer thickness in the X direction ranging from about 3 nm to about 15 nm.

The inner spacers 40 of each of the first dielectric units 41 are respectively formed beneath two end portions of a respective one of the n-channels 21 in the stacks 211, 212 so as to separate each of the gate structures 931, 932 from two corresponding adjacent ones of the n-type source/drain portions 23. The inner spacers 40 of each of the second dielectric units 42 are respectively formed beneath two end portions of a respective one of the p-channels 31 in the stacks 311, 312 so as to separate each of the gate structures 931, 932 from two corresponding adjacent ones of the p-type source/drain portions 33. In some embodiments, the inner spaces 40 may include a silicon oxide (e.g., SiO₂) based dielectric material, a silicon oxycarbide (SiOC) based dielectric material, a silicon oxynitride (SiON) based dielectric material, a silicon oxycarbonitride (SiOCN) based dielectric material, air gap, other suitable materials, or combinations thereof. Other insulating materials suitable for the inner spacers 40 are within the contemplated scope of the present disclosure. In some embodiments, a dielectric constant of the material(s) of the inner spacers 40 may be lower or higher than a dielectric constant of the material(s) of the spacers 951, 952, 953, 954. In some embodiments, each of the inner spacers 40 has a second spacer thickness in the X direction ranging from about 1 nm to about 12 nm. In some embodiments, the first spacer thickness is larger than the second spacer thickness by about 0.5 nm to about 3 nm.

In some embodiments, the cut-metal dielectric portions 94 are made of a dielectric material, such as silicon nitride (Si₃N₄), a nitride based dielectric layer, silicon oxide (SiO₂), silicon oxycarbide (SiOC), silicon oxynitride (SiON), silicon oxycarbonitride (SiOCN), a carbon content oxide, nitrogen content oxide, carbon and nitrogen content oxide, metal oxide dielectric, hafnium dioxide (HfO₂), tantalum oxide (Ta₂O₅), titanium oxide (TiO₂), zirconium oxide (ZrO₂), aluminum oxide (Al₂O₃), yttrium oxide (Y₂O₃), multiple metal content oxide, or combinations thereof. Other suitable materials for the cut-metal dielectric portions 94 are within the contemplated scope of the present disclosure.

In some embodiments, the first semiconductor structure further includes first anti-punch through regions APT1 and second anti-punch through regions APT2. Each of the first anti-punch through regions APT1 is formed in the p-type well and between the two adjacent ones of the first isolation features 22. A conductivity type of the first anti-punch through regions APT1 is the same as the conductivity type of the p-type well, and a dopant concentration of the first anti-punch through regions APT1 is greater than a dopant concentration of the p-type well. In some embodiments, the dopant concentration of the first anti-punch through regions APT1 may range from about 1E17 atoms/cm³ to about 1E19 atoms/cm³. In some embodiments, a difference between the dopant concentration of the first anti-punch through regions APT1 and the dopant concentration of the first doped semiconductor portion 221 is less than about two orders of magnitude. Each of the second anti-punch through regions APT2 is formed in the n-type well and between the two adjacent ones of the second isolation features 32. A conductivity type of the second anti-punch through regions APT2 is the same as the conductivity type of the n-type well, and a dopant concentration of the second anti-punch through regions APT2 is greater than a dopant concentration of the n-type well. In some embodiments, the dopant concentration of the second anti-punch through regions APT2 may range from about 1E17 atoms/cm³ to about 1E19 atoms/cm³. In some embodiments, a difference between the dopant concentration of the second anti-punch through regions APT2 and the dopant concentration of the second doped semiconductor portion 321 is less than about two orders of magnitude. In some embodiments, the anti-punch through regions APT1, APT2 may be omitted.

In some embodiments, the first semiconductor structure further includes cap portions 43 which are respectively formed on the gate structures 931, 932. The cap portions 43 may include a dielectric material, such as oxide-based dielectric materials (e.g., SiOC, SiON, SiOCN), nitrogen-based dielectric materials, metal oxide dielectric materials, Hf oxide (e.g., HfO₂), Ta oxide (e.g., Ta₂O₅), Ti oxide (e.g., TiO₂), Zr oxide (e.g., ZrO₂), A1 oxide (e.g., Al₂O₃), Y oxide (e.g., Y₂O₃), or combinations thereof. Other suitable materials for the cap portions 43 are within the contemplated scope of the present disclosure. In some embodiments, each of the cap portions 43 has a thickness ranging from about 2 nm to about 60 nm.

In some embodiments, the first semiconductor structure further includes a first inter-layer dielectric (ILD) layer 44 formed on the trench isolations 13, a second ILD layer 45 formed on the first ILD layer 44, and an inter-metal dielectric (IMD) layer 46 formed on the second ILD layer 45. The via contacts (VD) and the gate contacts (VG) (see also FIG. 1) are formed in the second ILD layer 45, and the conductive lines (CL) are formed in the IMD layer 46. The first ILD layer 44, the second ILD layer 45 and the IMD layer 46 may be made of the same or different dielectric materials, and each includes for example, but not limited to, silicon oxide, silicon nitride, SiON, phosphosilicate glass (PSG), borophosphosilicate glass (BPSG), spin-on glass (SOG), fluorosilicate glass (FSG), carbon-doped silicon oxide (e.g., SiCOH), xerogel, aerogel, parylene, divinylsiloxane-bis-benzocyclobutene-based (BCB-based) dielectric material, polyimide, or the like, or combinations thereof. Other materials suitable for the first and second ILD layers 44, 45 and the IMD layer 46 are within the contemplated scope of the present disclosure.

In some embodiments, the contact areas (MD), the via contacts (VD), the gate contacts (VG), and conductive lines (CL) may be each include a single metal material layer or multiple metal material layers and may be made of the same or different electrically conductive materials, such as Ti, TiN, Pt, W, Co, Ru, Mo, Ir, Rh, TaN, Cu, the like, or combinations thereof. Other materials suitable for the electrically conductive materials are within the contemplated scope of the present disclosure. In some embodiments, each of the conductive areas (MD) may be a self-aligned structure which is in direct contact with adjacent corresponding ones of the spacers 951, 952, 953, 954. In some other embodiments, each of the conductive areas (MD) may be a non-self-aligned structure which is spaced apart from the adjacent corresponding ones of the spacers 951, 952, 953, 954 by the first ILD layer 44.

In some embodiments, the first semiconductor structure further includes silicide layers 47 each of which is formed between one of the conductive areas (MD) and a respective one of the n-type source/drain portions 23 and the p-type source/drain portions 33. The silicide layers 47 may include silicon (from the n-type source/drain portions 23 or the p-type source/drain portions 33) and at least one metal element including, for example, but not limited to, aluminum, titanium, nickel, cobalt, other suitable materials, or combinations thereof. Other materials suitable for the silicide layers 47 are within the contemplated scope of the present disclosure.

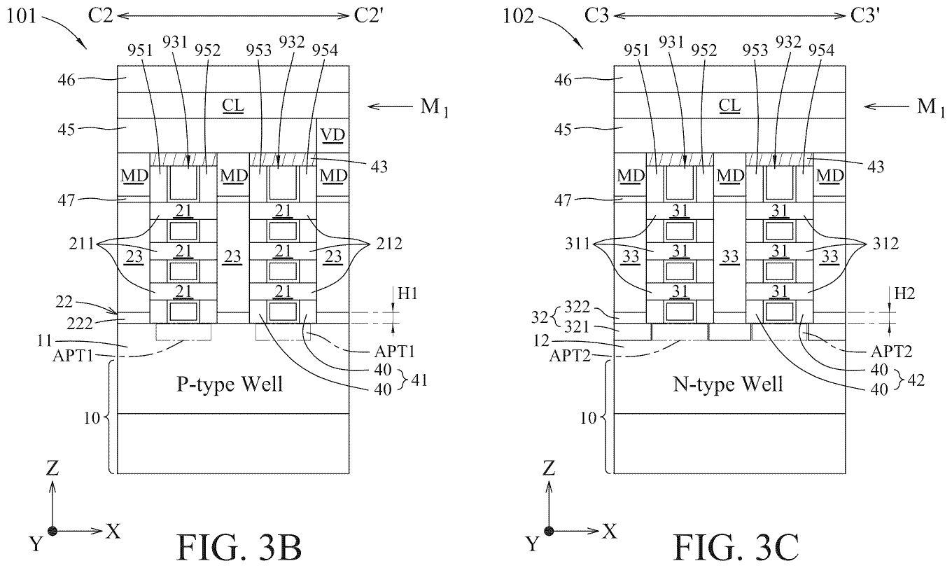

FIGS. 3A, 3B and 3C are schematic sectional views of a second semiconductor structure which are respectively taken long line C1-C1′, line C2-C2′, and line C3-C3′ of FIG. 1 in accordance with some other embodiments. The sectional view of the second semiconductor structure taken along line C4-C4′ of FIG. 1 is similar to that shown in FIG. 2D, and thus is not shown for the sake of brevity. The second semiconductor structure illustrated by FIGS. 3A, 3B and 3C are respectively similar to FIGS. 2A, 2B and 2C but in FIGS. 3A and 3B, the first doped semiconductor region 221 shown in FIGS. 2A and 2B is omitted.

As shown in FIGS. 3A and 3B, the first insulating portion 222 is in direct contact with the first semiconductor fin 11 (i.e., the first insulating portion 222 is in direct contact with the p-type well). Since a p-n junction is absent at an interface between the first insulating portion 222 and the the p-type well, in the second semiconductor structure, the first insulating portion 222 has a first dielectric thickness (H1) that is greater than a second dielectric thickness (H2) of the second insulating portion 322, so as to avoid a leakage current among the n-type source/drain portions 23 and the p-type well. In some embodiments, the first dielectric thickness (H1) is greater than the second dielectric thickness (H2) by about 0.5 nm to about 3 nm.

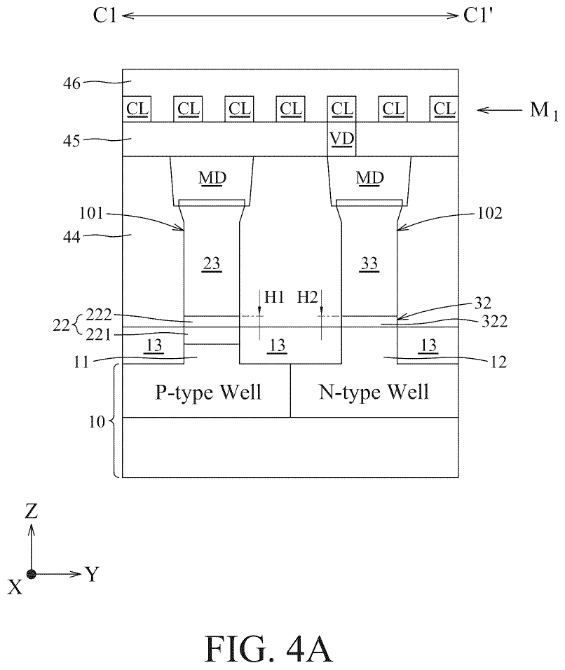

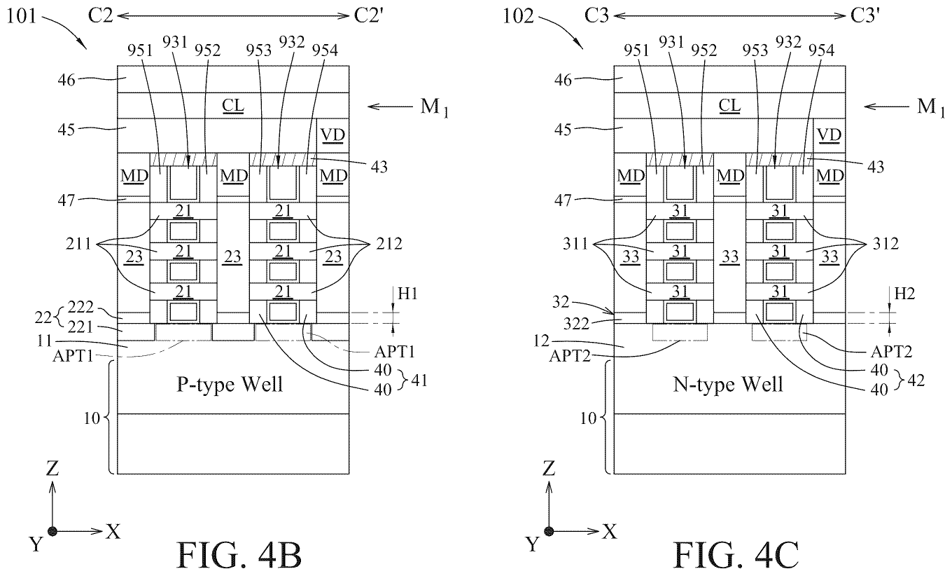

FIGS. 4A, 4B and 4C are schematic sectional views of a third semiconductor structure which are respectively taken long line C1-C1′, line C2-C2′, and line C3-C3′ of FIG. 1 in accordance with some other embodiments. The sectional view of the third semiconductor structure taken along line C4-C4′ of FIG. 1 is similar to that shown in FIG. 2D, and thus is not shown for the sake of brevity. The third semiconductor structure illustrated by FIGS. 4A, 4B and 4C are respectively similar to FIGS. 2A, 2B and 2C but in FIGS. 4A and 4C, the second doped semiconductor region 321 shown in FIGS. 2A and 2C is omitted.

As shown in FIGS. 4A and 4C, the second insulating portion 322 is in direct contact with the second semiconductor fin 12 (i.e., the second insulating portion 322 is in direct contact with the n-type well). Since a p-n junction is absent at an interface between the second insulating portion 322 and the n-type well, in the third semiconductor structure, the second insulating portion 322 has a second dielectric thickness (H2) that is greater than a first dielectric thickness (H1) of the first insulating portion 222, so as to avoid a leakage current among the p-type source/drain portions 33 and the n-type well. In some embodiments, the first dielectric thickness (H1) is smaller than the second dielectric thickness (H2) by about 0.5 nm to about 3 nm.

In some alternative embodiments, each of the first, second, and third semiconductor structure may further include additional features, and/or some features present in each of the first, second, and third semiconductor structure may be modified, replaced, or eliminated without departure from the spirit and scope of the present disclosure. In some embodiments, in the case that each of the semiconductor devices 101, 102 is formed as a complementary field-effect transistor (CFET) structure which includes a lower GAAFET and an upper GAAFET sequentially formed on the substrate in the Z direction, the CFET structure may be provided with the isolation features which are respectively formed beneath the source/drain portions of the lower GAAFET. In some other embodiments, in the case that each of the semiconductor devices 101, 102 is formed as a fork-sheet structure which includes two GAAFETs spaced part from each other in the Y direction through a wall portion, the fork-sheet structure may be provided with the isolation features which are respectively formed beneath the source/drain portions of the two GAAFETs. In yet some other embodiments, in the case that each of the semiconductor devices 101, 102 is formed as a vertical GAA structure which includes a lower source/drain portion and an upper source/drain portion which are respectively proximate to and distal from the substrate, and at least one channel extending between the lower and upper source/drain portions, the vertical GAA structure may be provided with a single isolation feature which is formed between the lower source/drain portion and the substrate.

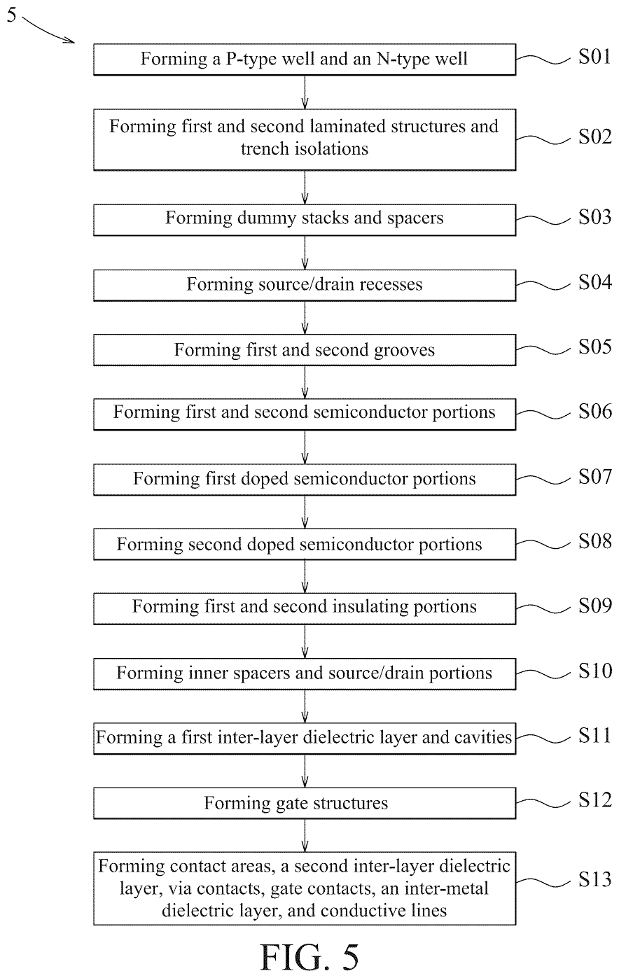

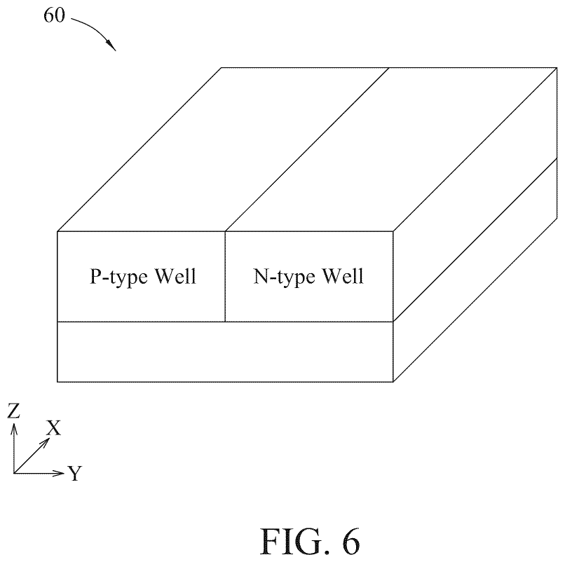

FIG. 5 is a flow diagram illustrating a method 5 for manufacturing a semiconductor structure (for example, but not limited to, the first semiconductor structure shown in FIGS. 2A to 2D) in accordance with some embodiments. The method 5 may include steps S01 to S13. FIGS. 6 to 21C illustrate schematic views of intermediate stages of the method 5 in accordance with some embodiments. Similar numerals from the above-mentioned embodiments have been used where appropriate, with some construction differences being indicated with different numerals.

Referring to FIG. 5 and the example illustrated in FIG. 6, the method 5 begins at step S01, where a starting substrate 60 is implanted so as to form the p-type well and the n-type well in an upper portion of the starting substrate 60. In some embodiments, formation of each of the p-type well and the n-type well includes (i) forming a patterned photoresist layer (not shown) partially on the starting substrate 60 by, for example, but not limited to, a spin coating, followed by an exposure process and a development process so as to expose a portion of the starting substrate 60 which is in position corresponding to the p-type well (or the n-type well) to be formed, (ii) implanting the p-type dopants (or the n-type dopants) into the exposed portion of the starting substrate 60, and (iii) removing the patterned photoresist layer by, for example, but not limited to, an ashing process and/or a photoresist stripping process.

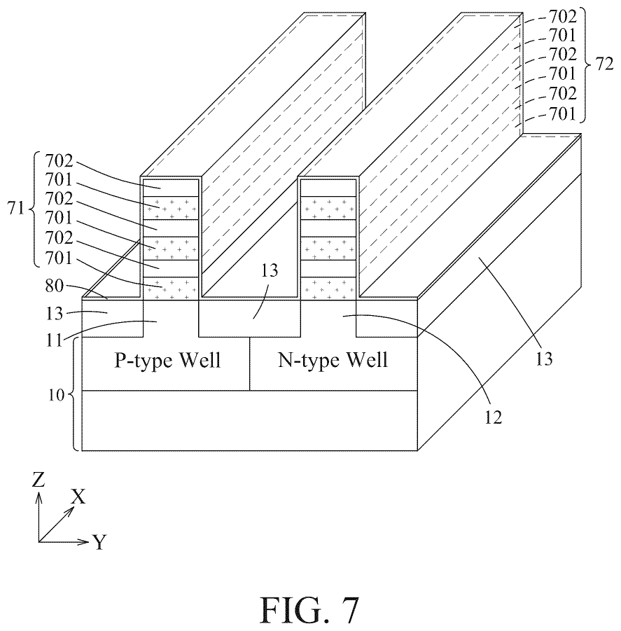

Referring to FIG. 5 and the example illustrated in FIG. 7, the method 5 proceeds to step S02, where a first laminated structure 71 and a second laminated structure 72 are respectively formed on the p-type well and the n-type well. Afterwards, the starting substrate 60 is patterned into the substrate 10 and the semiconductor fins 11, 12 by an etching process, and then the trench isolations 13 are formed to alternate with the semiconductor fins 11, 12. FIG. 7 is a schematic perspective view similar to that of FIG. 6, but illustrating the structure after step S02.

In step S02, the p-type well shown in FIG. 6 is patterned to form the first semiconductor fin 11, and thus the first semiconductor fin 11 includes the p-type dopants to have a p-type conductivity; and the n-type well shown in FIG. 6 is patterned to form the second semiconductor fin 12, and thus the second semiconductor fin 12 includes the n-type dopants to have an n-type conductivity.

After step S02, the laminated structures 71, 72 are respectively formed on the semiconductor fins 11, 12 and each is elongated in the X direction. Each of the laminated structures 71, 72 includes a plurality of first nanosheets 701 (three of which are shown in FIG. 7) and a plurality of second nanosheets 702 (three of which are shown in FIG. 7) disposed to alternate with the first nanosheets 701 in the Z direction. In some embodiments, an uppermost one of the second nanosheets 702 is disposed over an uppermost one of the first nanosheets 701 opposite to the substrate 10. In some embodiments, a lowermost one of the second nanosheets 702 is spaced apart from a corresponding one of the semiconductor fins 11, 12 by a lowermost one of the first nanosheets 701. In some embodiments, the second nanosheets 702 in the first laminated structure 71 include the semiconductor material of the n-channels 21, and the second nanosheets 702 in the second laminated structure 72 include the semiconductor material of the p-channels 31. In some embodiments, in each of the laminated structures 71, 72, the first nanosheets 701 are made of a material different from the semiconductor material of the second nanosheets 702, such that the first nanosheets 701 may be selectively removed with the second nanosheets 702 being substantially intact due to different etching selectivities. In some embodiments, the first nanosheets 701 are made of silicon germanium, and the second nanosheets 702 are made of silicon. Other materials suitable for the first nanosheets 701 and the second nanosheets 702 are within the contemplated scope of the present disclosure. In some embodiments, formation of the laminated structures 71, 72 may include (i) forming a film stack (not shown) on the starting substrate 60 (see FIG. 6) by chemical vapor deposition (CVD), atomic layer deposition (ALD), an epitaxial growth process (such as molecular-beam epitaxy (MBE), selective area epitaxy (SAE), etc.), or other suitable deposition techniques, and (ii) patterning the film stack and the starting substrate 60 by a photolithography process so that the film stack is patterned into the laminated structures 71, 72 each having a predetermined dimension in the Y direction and the starting substrate 60 is patterned into the substrate 10 and the first and second semiconductor fins 11, 12 on the substrate 10.

In some embodiments, formation of the trench isolations 13 may include (i) forming an isolation layer over the substrate 10 and the laminated structures 71, 72 followed by a planarization process, for example, but not limited to, chemical mechanism polishing (CMP), to form isolation regions (not shown), (ii) recessing the isolation regions such that the isolation regions are respectively formed into the trench isolations 13.

In some embodiments, after formation of the trench isolations 13, a sacrificial silicon layer 80 (optional) is formed to cover the laminated structures 71, 72 so as to protect the first and second nanosheets 701, 702 from oxidation during formation of a dummy gate dielectric 801 in a subsequent step. The sacrificial silicon layer 80 may be patterned and treated to serve as a part of the dummy gate dielectric 801. In some embodiments, the sacrificial silicon layer 80 has a thickness ranging from about 0.3 nm to about 3 nm.

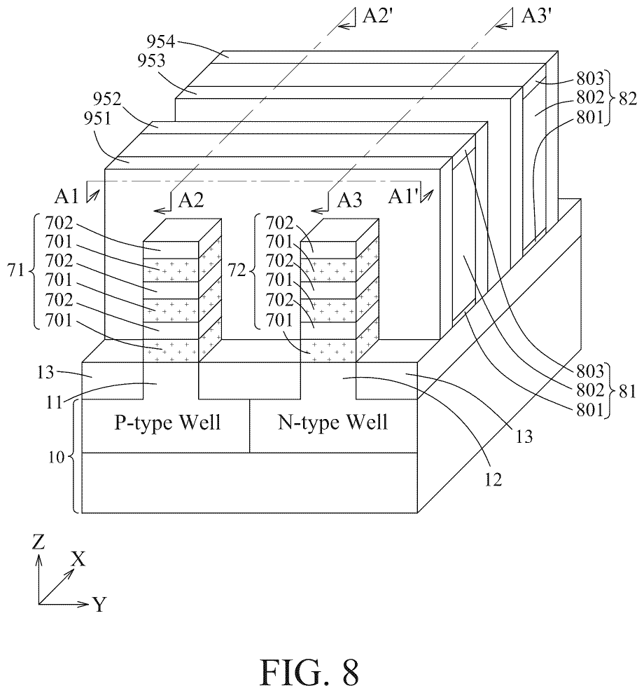

Referring to FIG. 5 and the example illustrated in FIG. 8, the method 5 proceeds to step S03, where dummy stacks 81, 82 and the spacers 951, 952, 953, 954 are formed. FIG. 8 is a schematic perspective view similar to that of FIG. 7, but illustrating the structure after step S03.

In some embodiments, the dummy stacks 81, 82 are each elongated in the Y direction and spaced apart from each other in the X direction. Each of the dummy stacks 81, 82 includes a dummy gate dielectric 801 disposed over the laminated structures 71, 72, a dummy gate portion 802 disposed on the dummy gate dielectric 801, and a hard mask 803 disposed on the dummy gate portion 802. In some embodiments, the dummy gate dielectric 801 may include silicon oxide, silicon nitride, silicon oxynitride, high dielectric constant (k) materials, other suitable dielectric materials, or combinations thereof. In some embodiments, the dummy gate portion 802 may include polycrystalline silicon, single crystalline silicon, amorphous silicon, or combinations thereof. In some embodiments, the hard mask 803 may include silicon nitride, silicon oxide, silicon oxynitride, or combinations thereof. Other materials suitable for the dummy stacks 81, 82 are within the contemplated scope of the present disclosure. In some embodiments, formation of the dummy stacks 81, 82 over the laminated structures 71, 72 may include (i) sequentially forming a first dummy layer (not shown) for forming the dummy gate dielectric 801 and a second dummy layer (not shown) for forming the dummy gate portion 802 over the laminated structures 71, 72 by CVD, ALD, physical vapor deposition (PVD), or other suitable deposition techniques, (ii) performing a planarization process (e.g., chemical mechanical polishing) to obtain a planar upper surface of the second dummy layer, (iii) forming a third dummy layer (not shown) for forming the hard mask 803 on the planarized second dummy layer, and (iv) patterning the first dummy layer, the planarized second dummy layer and the third dummy layer by a photolithography process, thereby obtaining the dummy stacks 81, 82. In some embodiments, during formation of the first dummy layer, the sacrificial silicon layer 80 (see FIG. 7) may be oxidized and/or treated (e.g., being subjected to nitridation or other suitable treatments) to serve as a portion of the first dummy layer.

In some embodiments, the spacers 951, 952, 953, 954 may be formed by CVD, ALD, PVD, or other suitable deposition techniques, followed by an anisotropic etching process to expose the dummy stacks 81, 82 and portions of the laminated structures 71, 72. In some embodiments, during formation of the spacers 951, 952, 953, 954, a material for forming the spacers 951, 952, 953, 954 is also formed into multi-pairs of fin sidewalls (not shown). Each pair of the fin sidewalls are formed at two opposite sides of a respective one of the exposed portions of the laminated structures 71, 72.

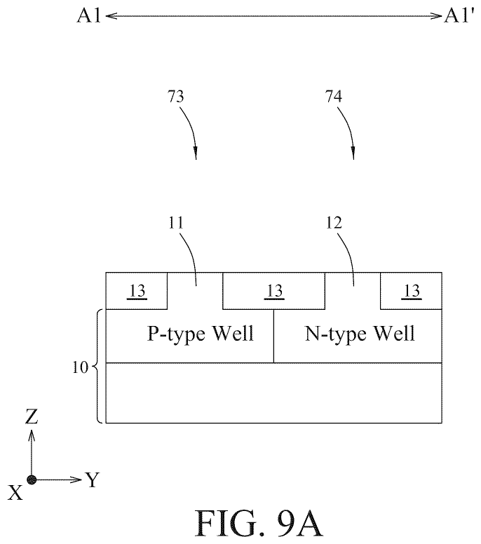

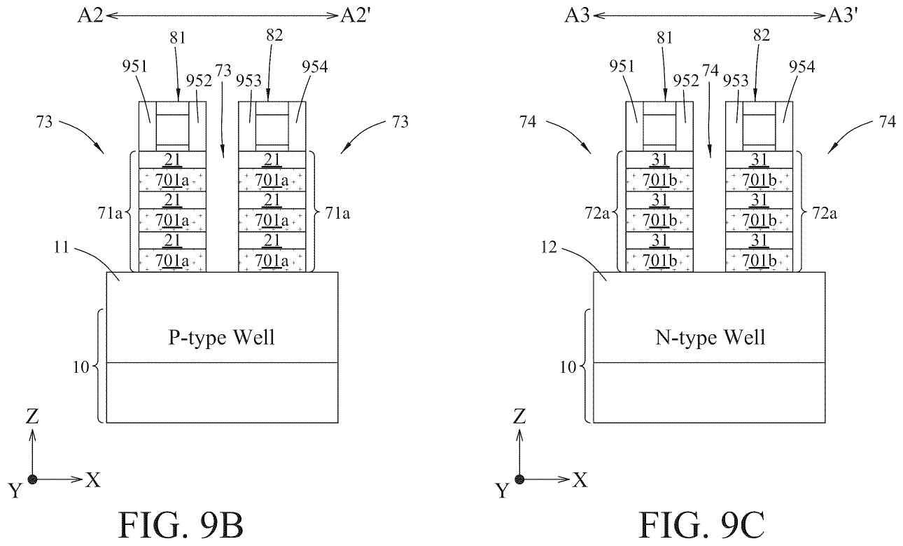

Referring to FIG. 5 and the examples illustrated in FIGS. 9A, 9B and 9C, the method 5 proceeds to step S04, where the exposed portions of the laminated structures 71, 72 (see FIG. 8) and the semiconductor fins 11, 12 are patterned to form source/drain recesses 73, 74 by an etching technique (for example, but not limited to, dry etching, wet etching, or a combination thereof). FIGS. 9A, 9B and 9C are schematic sectional view respectively taken along line A1-A1′, line A2-A2′ and line A3-A3′ of FIG. 8, but illustrating the structures after step S04.

After step S04, the first laminated structure 71 (see FIG. 8) is formed into first stacking portions 71a, and the second laminated structure 72 (see FIG. 8) is formed into second stacking portions 72a. Each of the stacking portions 71a includes the n-channels 21 which are respectively formed from the second nanosheets 702 of the first laminated structure 71, and nanosheet segments 701a which are respectively formed from the first nanosheets 701 of the first laminated structure 71. Each of the second stacking portions 72a includes the p-channels 31 which are respectively formed from the second nanosheets 702 of the second laminated structure 72, and nanosheet segments 701b which are respectively formed from the first nanosheets 701 of the second laminated structure 72.

The first source/drain recesses 73 are disposed to alternate with the first stacking portions 71a in the X direction, and the second source/drain recesses 74 are disposed to alternate with the second stacking portions 72a in the X direction.

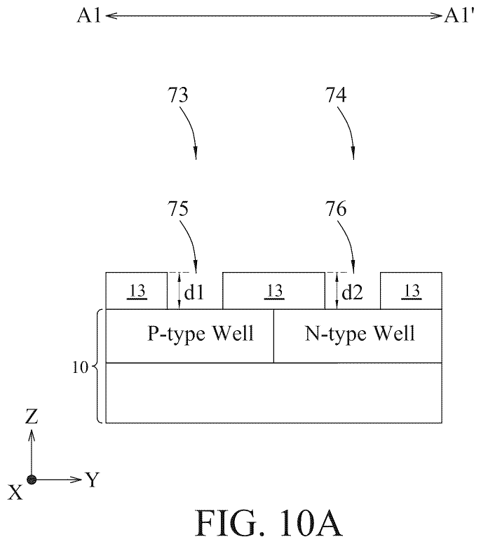

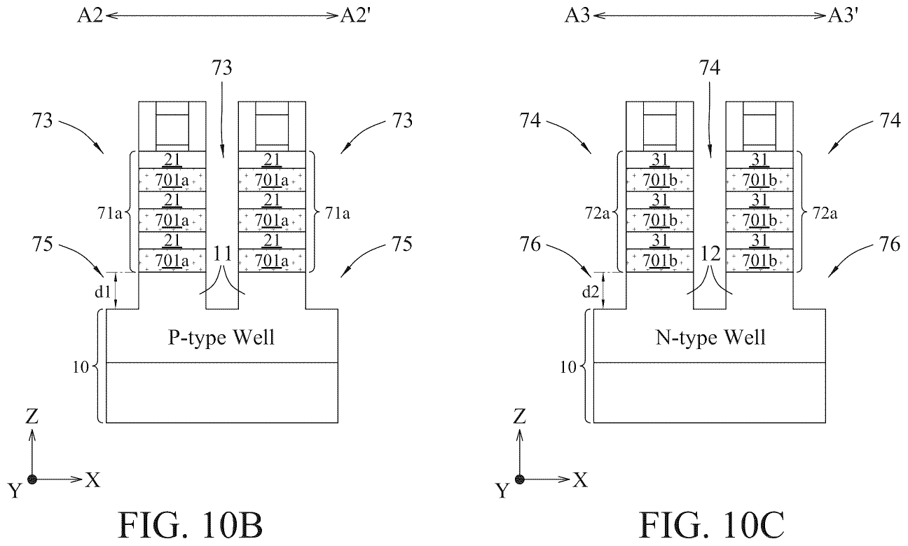

Referring to FIG. 5 and the examples illustrated in FIGS. 10A, 10B and 10C, the method 5 proceeds to step S05, where the first semiconductor fin 11 is etched to form first grooves 75 therein, and the second semiconductor fin 12 is etched to form second grooves 76 therein. FIGS. 10A, 10B and 10C are schematic sectional view respectively similar to those of FIGS. 9A, 9B and 9C, but illustrating the structures after step S05.

The first grooves 75 are respectively recessed from bottom surfaces of the first source/drain recesses 73 by a depth, and the second grooves 76 are respectively recessed from bottom surfaces of the second source/drain recesses 74 by a depth. In some embodiments, the grooves 75, 76 are formed by an etching technique (for example, but not limited to, dry etching, wet etching, or a combination thereof). In some embodiments, the depth (d1, d2) of each of the grooves 75, 76 ranges from about 5 nm to about 70 nm.

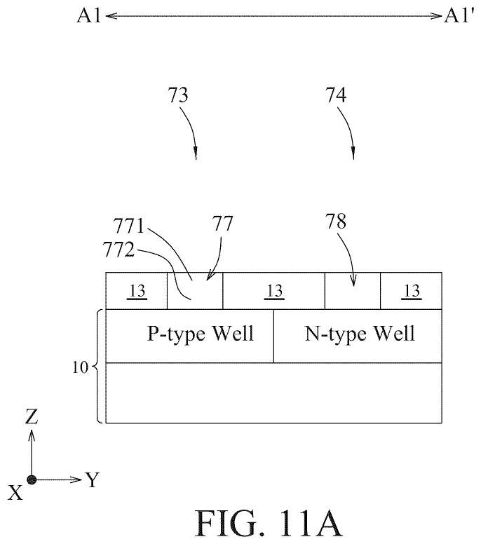

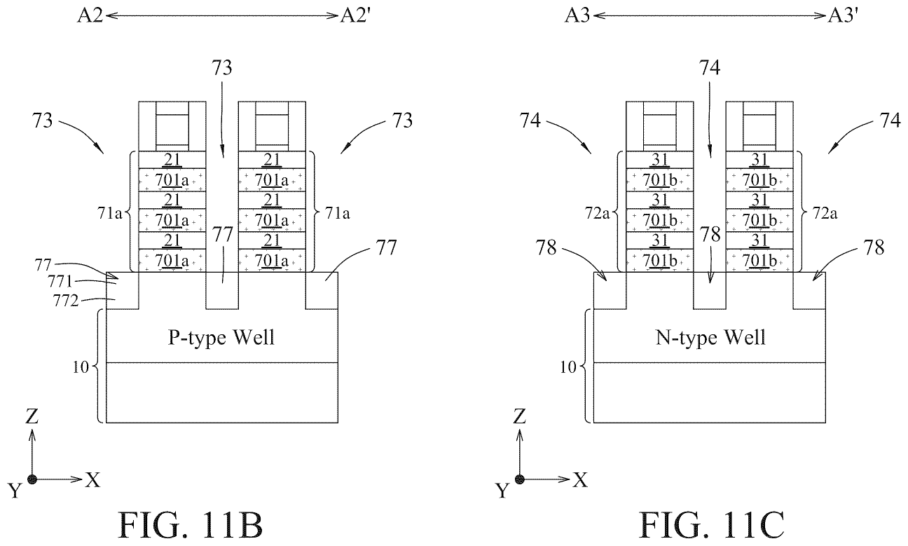

Referring to FIG. 5 and the examples illustrated in FIGS. 11A, 11B and 11C, the method 5 proceeds to step S06, where first semiconductor portions 77 are respectively formed in the first grooves 75 (see FIGS. 10A and 10B), and second semiconductor portions 78 are respectively formed in the second grooves 76 (see FIGS. 10A and 10B). FIGS. 11A, 11B and 11C are schematic sectional view respectively similar to those of FIGS. 10A, 10B and 10C, but illustrating the structures after step S06.

In some embodiments, the semiconductor portions 77, 78 are respectively formed to fill the grooves 75, 76. In some embodiments, a level of an upper surface of each of the semiconductor portions 77, 78 may be slightly higher or lower than or equal to a bottom surface of a corresponding adjacent one of the stacking portions 71a, 72a due to variation of process parameter(s) (e.g., process time, temperatures, etc.) for forming the semiconductor portions 77, 78.

In some embodiments, each of the first semiconductor portions 77, 78 includes includes a semiconductor material (such as the examples of the semiconductor material for forming the substrate 10). In some embodiments, each of the first semiconductor portions 77, 78 is made of silicon. In some embodiments, each of the first semiconductor portions 77, 78 is formed by an epitaxial growth process (such as molecular-beam epitaxy (MBE), selective area epitaxy (SAE), etc.), or other suitable deposition techniques.

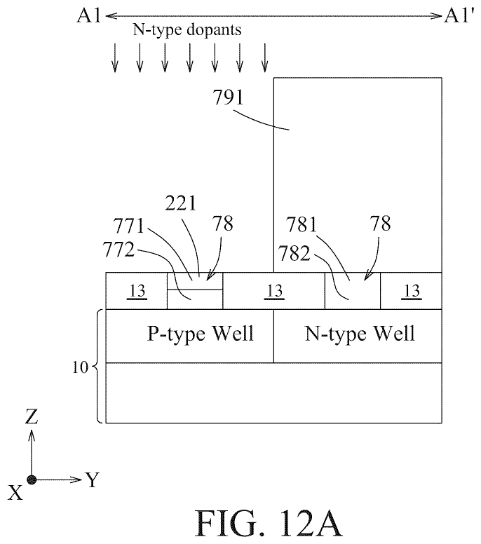

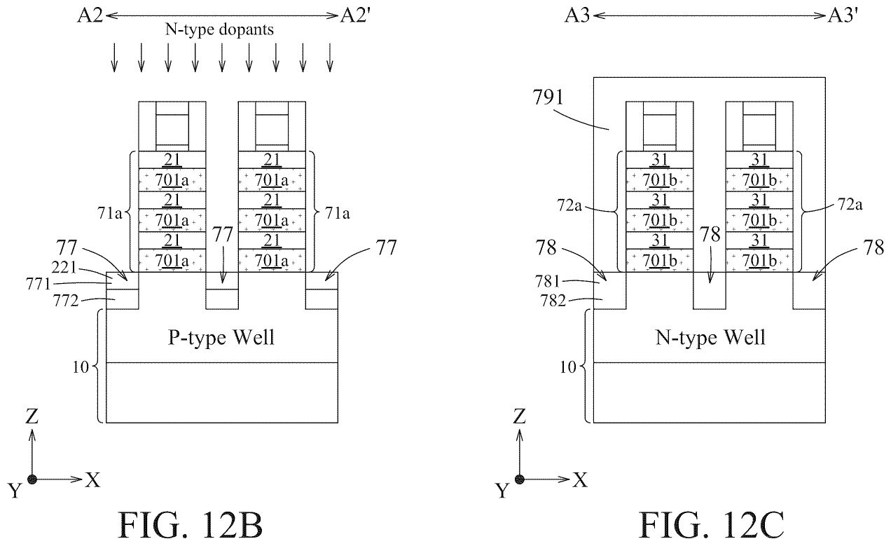

Referring to FIG. 5 and the examples illustrated in FIGS. 12A, 12B and 12C, the method 5 proceeds to step S07, where the first semiconductor portions 77 (see FIGS. 11A and 11B) are implanted with n-type dopants to form the first doped semiconductor portions 221 of the first isolation features 22 (see FIGS. 2A and 2B), while the structure above the n-type well is protected by a patterned photoresist layer 791. FIGS. 12A, 12B and 12C are schematic sectional view respectively similar to those of FIGS. 11A, 11B and 11C, but illustrating the structures after step S07.

Each of the first semiconductor portions 77 has an upper region 771 spaced apart from the substrate 10, and a lower region 772 connected to the substrate 10. In some embodiments, each of the first semiconductor portions 77 is partially implanted with the n-type dopants such that a doping concentration of the n-type dopants at the upper region 771 is greater than a doping concentration of the n-type dopants at the lower region 772. After the implantation of the first semiconductor portions 77, the implanted upper region 771 serves as the first doped semiconductor portion 221 of a respective one of the first isolation features 22 (see also FIGS. 2A to 2C). In some embodiments, the thickness of the first doped semiconductor portion 221 may be controlled by adjusting an implantation depth of the n-type dopants utilized in the implantation of the first semiconductor portions 77.

After step S07 and before proceeding to the next step, the patterned photoresist layer 791 may be removed by, for example, but not limited to, an ashing process and/or a photoresist stripping process.

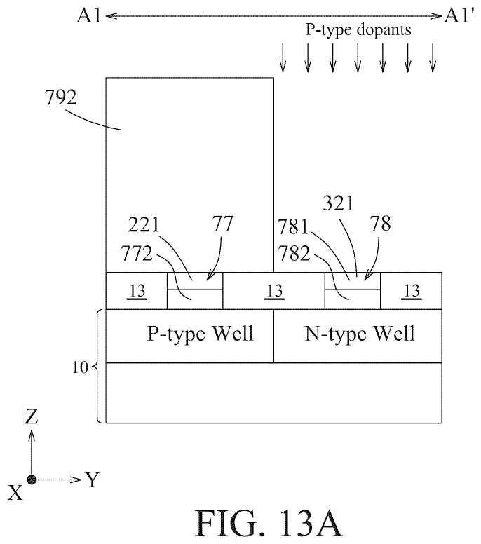

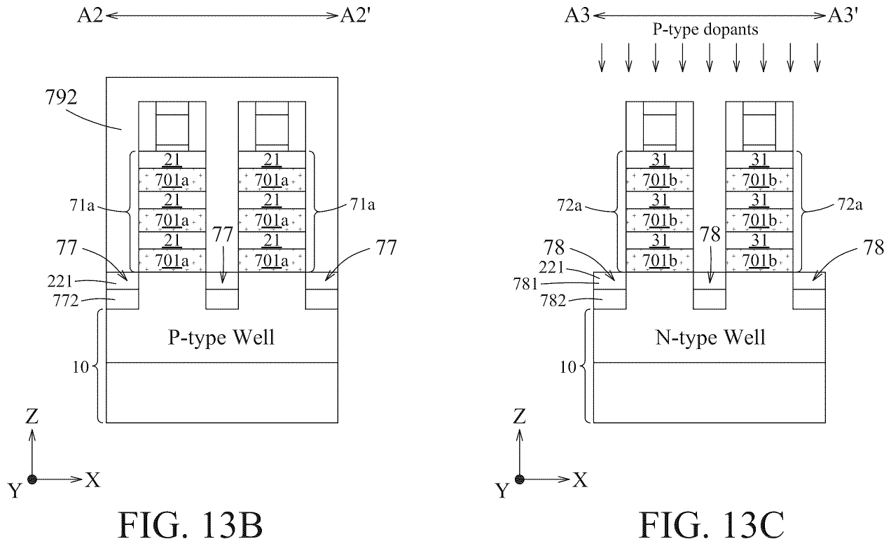

Referring to FIG. 5 and the examples illustrated in FIGS. 13A, 13B and 13C, the method 5 proceeds to step S08, where the second semiconductor portions 78 (see FIGS. 12A and 12C) are implanted with p-type dopants to form the second doped semiconductor portions 321 of the second isolation features 32 (see FIGS. 2A and 2C), while the structure above the p-type well is protected by a patterned photoresist layer 792. FIGS. 13A, 13B and 13C are schematic sectional view respectively similar to those of FIGS. 12A, 12B and 12C, but illustrating the structures after step S08.

Each of the second semiconductor portions 78 has an upper region 781 spaced apart from the substrate 10, and a lower region 782 connected to the substrate 10. In some embodiments, each of the second semiconductor portions 78 is partially implanted with the p-type dopants such that a doping concentration of the p-type dopants at the upper region 781 is greater than a doping concentration of the p-type dopants at the lower region 782. After the implantation of the second semiconductor portions 78, the implanted upper region 781 serves as the second doped semiconductor portion 321 of a respective one of the second isolation features 32 (see also FIGS. 2A to 2C). In some embodiments, the thickness of the second doped semiconductor portion 321 may be controlled by adjusting an implantation depth of the p-type dopants utilized in the implantation of the second semiconductor portions 78.

After step S08 and before proceeding to the next step, the patterned photoresist layer 792 may be removed by, for example, but not limited to, an ashing process and/or a photoresist stripping process.

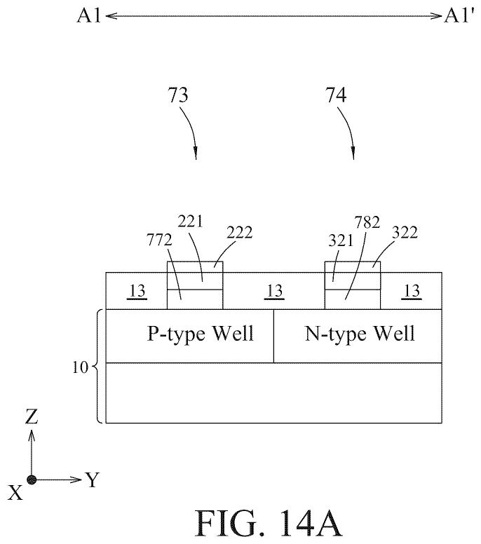

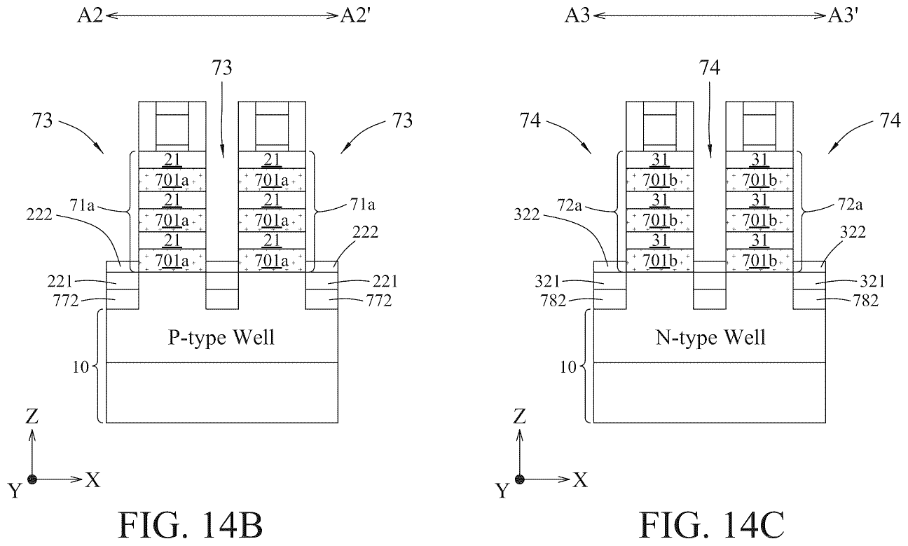

Referring to FIG. 5 and the examples illustrated in FIGS. 14A, 14B and 14C, the method 5 proceeds to step S09, where the first insulating portions 222 of the first isolation features 22 (see also FIGS. 2A and 2B) and the second insulating portions 322 of the second isolation features 32 (see also FIGS. 2A and 2C) are formed. FIGS. 14A, 14B and 14C are schematic sectional view respectively similar to those of FIGS. 13A, 13B and 13C, but illustrating the structures after step S09.

In some embodiments, the first insulating portions 222 may be formed by a selective deposition process or other suitable deposition techniques. In the selective deposition process, a material for forming the first insulating portions 222 is deposited in the first source/drain recesses 73 by CVD, ALD, PVD, or other suitable deposition techniques, such that a thickness of the material deposited at the bottom of each first source/drain recess 73 for forming the first insulating portions 222 is greater than a thickness of the material deposited on the side surface of each first source/drain recess 73 for forming the first insulating portions 222. Afterwards, an isotropic etching process is performed such that the material deposited on the side surface of each first source/drain recess 73 for forming the first insulating portions 222 is removed, whereas a portion of the material remains at the bottom of each first source/drain recess 73 and serves as the first insulating portions 222. In some embodiments, the second insulating portions 322 may be formed in a manner similar to that of the first insulating portions 222. In some embodiments, the insulating portions 222, 322 are formed at the same time.

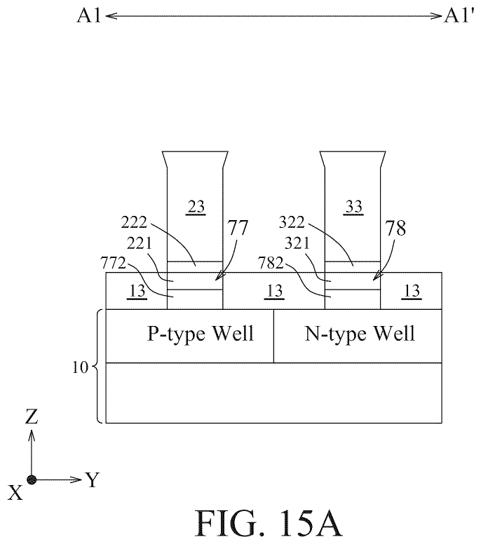

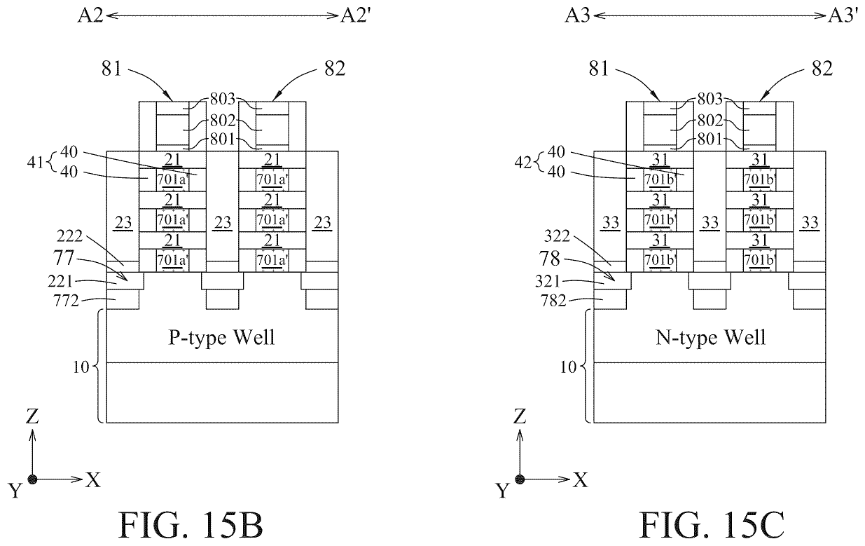

Referring to FIG. 5 and the examples illustrated in FIGS. 15A, 15B and 15C, the method 5 proceeds to step S10, where the inner spacers 40 of each of the dielectric units 41, 42, the n-type source/drain portions 23 and the p-type source/drain portions 33 are formed. FIGS. 15A, 15B and 15C are schematic sectional view respectively similar to those of FIGS. 14A, 14B and 14C, but illustrating the structures after step S10.

In some embodiments, step S10 may include multiple sub-steps as described in the following.

First, two end portions of each of the nanosheet segments 701a, 701b (see FIGS. 14B and 14C) opposite to each other in the X direction are etched to form recesses (not shown) by an etching process while keeping the n-channels 21 and the p-channels 31 substantially intact. Then, the inner spacers 40 are formed by (i) depositing a low-k dielectric material for forming the inner spacers 40 is deposited to cover each of the etched nanosheet segments 701a′, 701b′ and fill the recesses by CVD, ALD, PVD, or other suitable deposition techniques, and (ii) removing excess portions of the low-k dielectric material by an anisotropic etching process such that the inner spacers 40 in each dielectric unit 41, 42 are respectively formed at two opposite sides of a respective one of the recessed nanosheet segments 701a′, 701b′.

After formation of the inner spacers 40, the n-type source/drain portions 23 and the p-type source/drain portions 33 are formed. The n-type source/drain portions 23 may be formed after or before formation of the p-type source/drain portions 33.

In some embodiments, the n-type source/drain portions 23 are respectively formed on the first insulating portions 222 of the first isolation features 22 by an epitaxial growth process, while the structure above the n-type well is protected by a patterned photoresist layer (not shown). The patterned photoresist layer on the n-type well is removed after the n-type source/drain portions 23 are formed.

In some embodiments, the p-type source/drain portions 33 are respectively formed on the second insulating portions 322 of the second isolation features 32 by an epitaxial growth process, while the structure above the p-type well is protected by a patterned photoresist layer (not shown). The patterned photoresist layer on the p-type well is removed after the p-type source/drain portions 33 are formed.

In some embodiments, the epitaxial growth process may include molecular-beam epitaxy (MBE), an epitaxial deposition/partial etch process, such as a cyclic deposition-etch (CDE) process and/or a selective epitaxial growth (SEG) process, but the disclosure is not limited to such.

In some embodiments, a thermal treatment, such as an annealing process, is performed after formation of the n-type source/drain portions 23 and the p-type source/drain portions 33. In some embodiments, the thermal treatment is performed to repair defects in the n-type source/drain portions 23 and the p-type source/drain portions 33. In some embodiments, during the thermal treatment, the p-type dopants in the first semiconductor fin 11 and the first upper portion of the substrate 10 diffuse into the lower region 772 of each of the first semiconductor portions 77 so as to permit the lower region 772 of each of the first semiconductor portions 77 to have a p-type conductivity. Therefore, the lower region 772 of each of the first semiconductor portions 77, the first upper portion of the substrate 10 and the first semiconductor fin 11 together serve as the p-type well. Meanwhile, the n-type dopants in the second semiconductor fin 12 and the second upper portion of the substrate 10 diffuse into the lower region 782 of each of the second semiconductor portions 78 so as to permit the lower region 782 of each of the second semiconductor portions 78 to have an n-type conductivity. Therefore, the lower region 782 of each of the second semiconductor portions 78, the second upper portion of the substrate 10 and the second semiconductor fin 12 together serve as the n-type well.

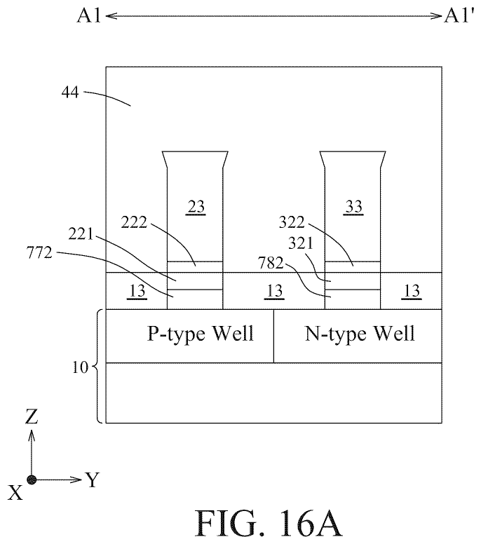

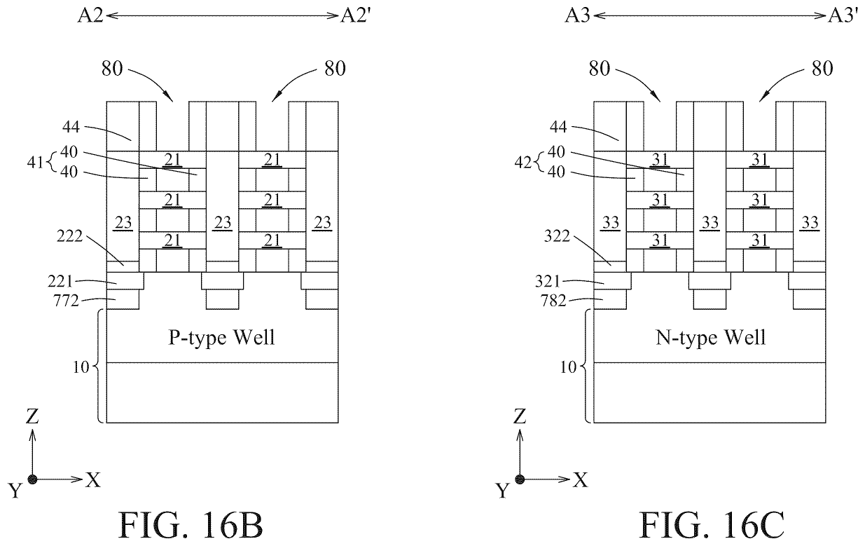

Referring to FIG. 5 and the examples illustrated in FIGS. 16A, 16B and 16C, the method 5 proceeds to step S11, where the first inter-layer dielectric (ILD) layer 44 is formed to cover the source/drain portions 23, 33, and the dummy stacks 81, 82 and the etched nanosheet segments 701a′, 701b′ (see FIGS. 15B and 15C) are removed to form cavities 80. FIGS. 16A, 16B and 16C are schematic sectional view respectively similar to those of FIGS. 15A, 15B and 15C, but illustrating the structures after step S11. In some embodiments, before forming the first ILD layer 44, a contact etch stop layer (CESL, not shown) may be formed previously. Possible materials for the CESL are similar to those for the first ILD layer 44 described above, but the CESL and the first ILD layer 44 are made of different materials.

In step S11, materials for forming the CESL and the first ILD layer 44 are subsequently deposited using CVD, PVD, ALD or other possible processes, followed by a planarization process to expose the dummy gate portions 802 of each of the dummy stacks 81, 82 (see FIGS. 15B and 15C) so as to obtain the CESL and the first ILD layer 44. Then, the dummy gate portions 802 and the dummy gate dielectric 801 of each of the dummy stacks 81, 82, and the etched nanosheet segments 701a′, 701b′ are removed to form the cavities 80 using a selective etching process (e.g., a wet etching process or other suitable processes) without damaging the n-channels 21 and the p-channels 31.

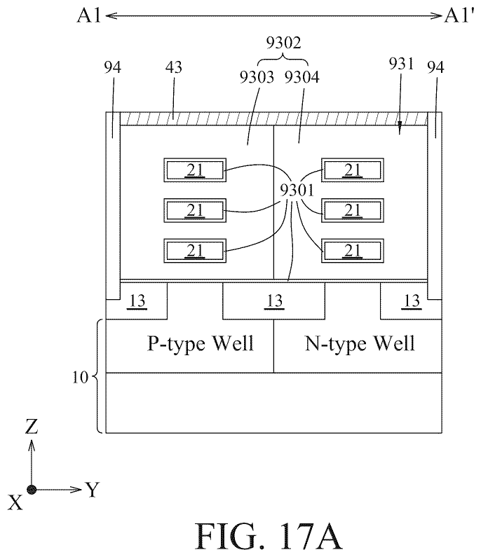

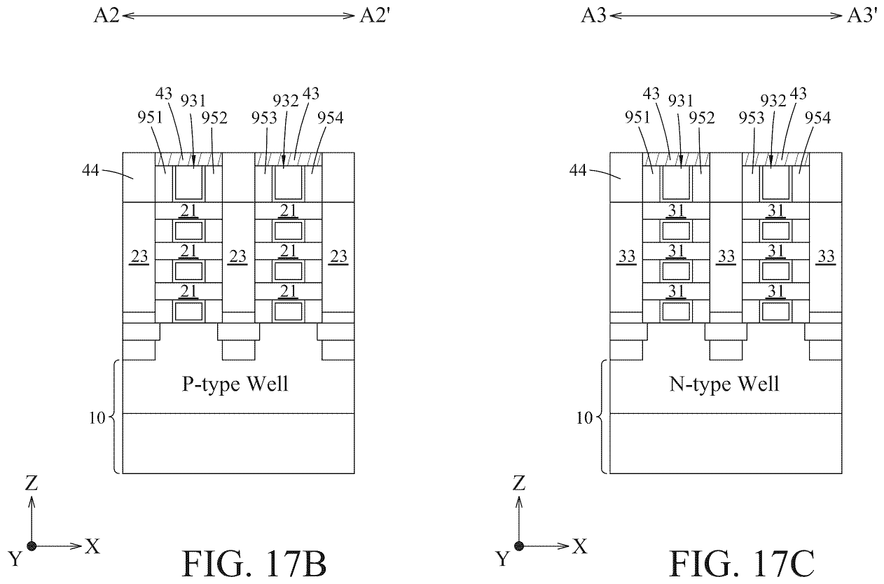

Referring to FIG. 5 and the examples illustrated in FIGS. 17A, 17B and 17C, the method 5 proceeds to step S12, where the gate structures 931, 932 are formed. FIGS. 17B and 17C are schematic sectional view respectively similar to those of FIGS. 16B and 16C, but illustrating the structures after step S12. FIG. 17A is another schematic section view taken in the Y direction illustrating the gate structure 931 formed after step S12 in accordance with some embodiments. In some embodiments, the cap portions 43 are formed over the gate structures 931, 932, respectively, and the cut-metal dielectric portions 94 are formed so that two ends of each of the gate structures 931, 932, which are opposite to each other in the Y direction, are in contact with two corresponding ones of the cut-metal dielectric portions 94.

In step S12, the materials for forming the gate dielectric 9301 and the gate electrodes 9302 are subsequently deposited using CVD, PVD, ALD or other suitable processes, followed by a planarization process to expose the first ILD layer 44. Then, the materials for forming the gate dielectric 9301 and the gate electrodes 9302 and the spacers 951, 952, 953, 954 are etched back to form grooves (not shown), and the grooves are refilled with a material for forming the cap portions 43 using CVD, PVD, ALD or other suitable processes, followed by another planarization process to expose the first ILD layer 44 so as to obtain the gate structures 931, 932 and the cap portions 43. Thereafter, by forming the cut-metal dielectric portions 94, a length of each of the gate structures 931, 932 in the Y direction is determined. The cut-metal dielectric portions 94 are formed by patterning the gate structures 931, 932, the cap portions 43 and portions of the trench isolations 13 to form deep slots (not shown), and the deep slots are refilled with a material for forming the cut-metal dielectric portions 94 using CVD, PVD, ALD or other suitable processes, followed by yet another planarization process to expose the first ILD layer 44.

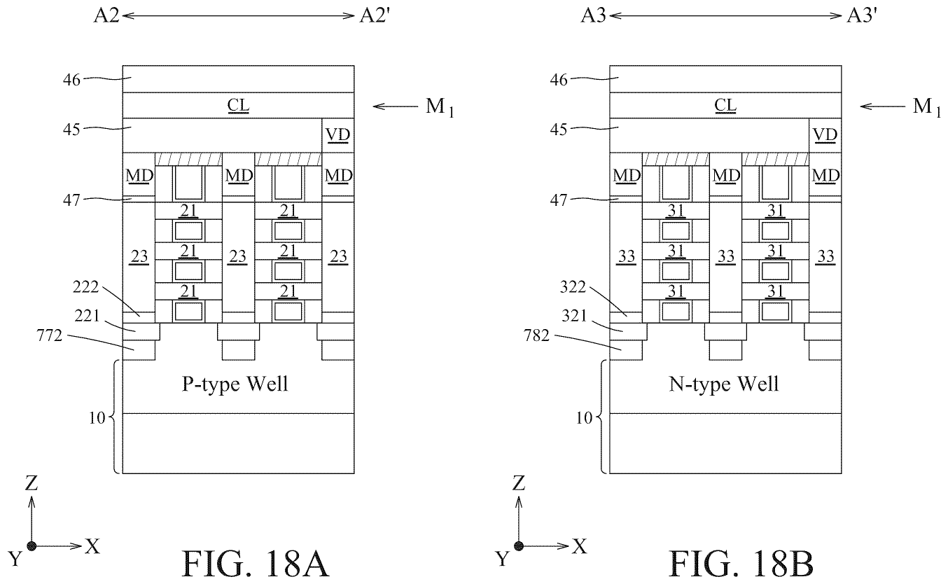

Referring to FIG. 5 and the examples illustrated in FIGS. 18A and, 18B, the method 5 proceeds to step S13, where the contact areas (MD), the second ILD layer 45, the via contacts (VD), the gate contacts (VG), the IMD layer 46, and the conductive lines (CL) are formed. In some embodiments, the silicide layers 47 are formed so as to reduce a contact resistance between each of the contact areas (MD) and a respective one of the n-type source/drain portions 23 and the p-type source/drain portions 33. FIGS. 18A and 18B are schematic sectional view respectively similar to those of FIGS. 17B and 17C, but illustrating the structures after step S13.

In some embodiments, the contact areas (MD) are formed in the first ILD layer 44 (see FIGS. 17B and 17C) by patterning the first ILD layer 44 to form contact holes (not shown) from which the source/drain portions 23, 33 are exposed. Then, the silicide layers 47 are formed by introducing the metal element(s) for forming the silicide layers 47 in upper portions of the source/drain portions 23, 33 by implantation process(es). Thereafter, a material for forming the contact areas (MD) is deposited to fill the contact holes, followed by a planarization process to expose the first ILD layer 44. The second ILD layer 45, the via contacts (VD), the gate contacts (VG), the IMD layer 46, and the conductive lines (CL) may be formed by a dual damascene process, a single damascene process, or other suitable back-end-of-line (BEOL) techniques.

In some embodiments, some steps in the method 5 may be modified, replaced, or eliminated without departure from the spirit and scope of the present disclosure.

For example, in some embodiments, step S07 (i.e., the implantation of the first semiconductor portions 77 as described above with reference to FIGS. 12A to 12C) may be performed after step S08 (i.e., the implantation of the second semiconductor portions 78 as described above with reference to FIGS. 13A to 13C).

In some another embodiments, the inner spacers 40 of each of the dielectric units 41, 42 (as described in step S10 with reference to FIGS. 15A to 15C) may be formed after step S05 (i.e., formation of the grooves 75, 76 as described above with reference to FIGS. 10A to 10C) and before step S06 (i.e., formation of the semiconductor portions 77, 78 as described above with reference to FIGS. 11A to 11C).

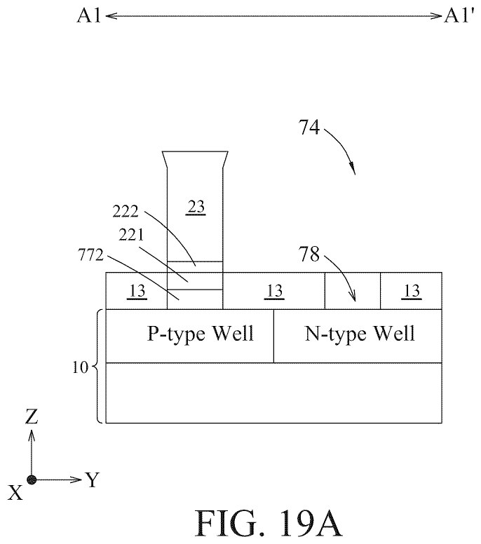

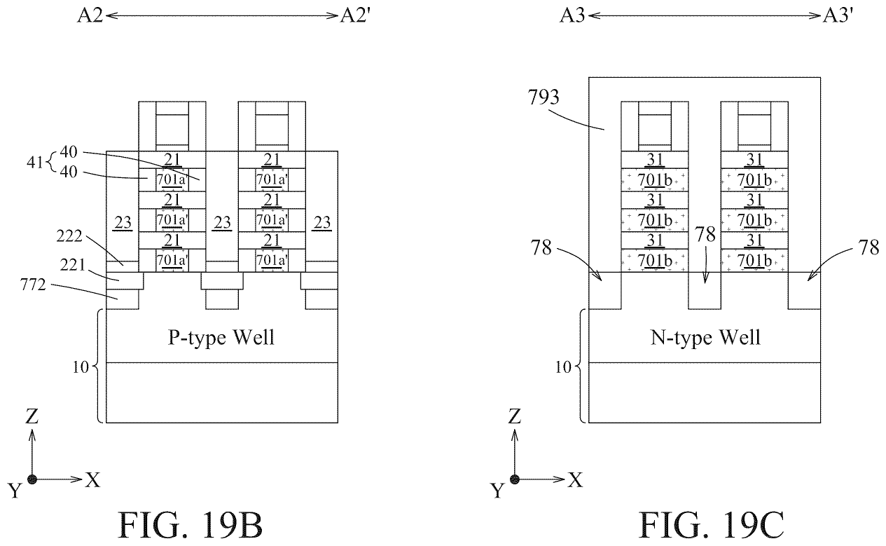

In yet some other embodiments, steps S07 to S10 may not be performed in the sequence described above. As shown in FIGS. 19A, 19B and 19C, the first doped semiconductor portions 221, the first insulating portions 222, the inner spacers 40 of the dielectric units 41, and the n-type source/drain portions 23 may be sequentially formed, while the structure above the n-type well is protected by a patterned photoresist layer 793. Afterwards, after the patterned photoresist layer 793 is removed and the structure above the p-type well is protected by another patterned photoresist layer (not shown), the second doped semiconductor portions 321, the second insulating portions 322, the inner spacers 40 of the dielectric units 42, and the p-type source/drain portions 33 (see FIG. 15C) may be sequentially formed. In other words, the n-type source/drains elements 23 and other elements therebeneath may be formed using the patterned photoresist layer 793, and the p-type source/drains elements 33 and other elements therebeneath may be formed using the another patterned photoresist layer.

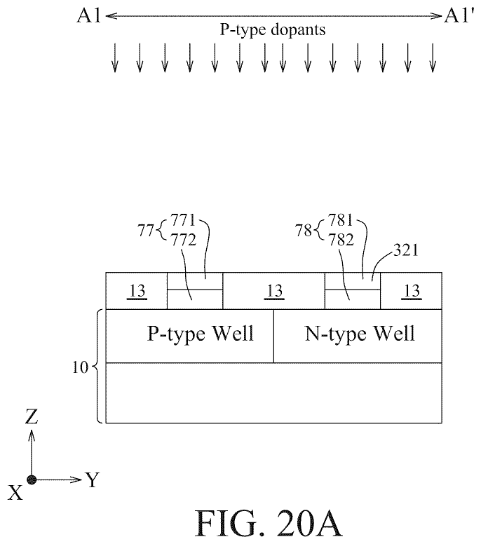

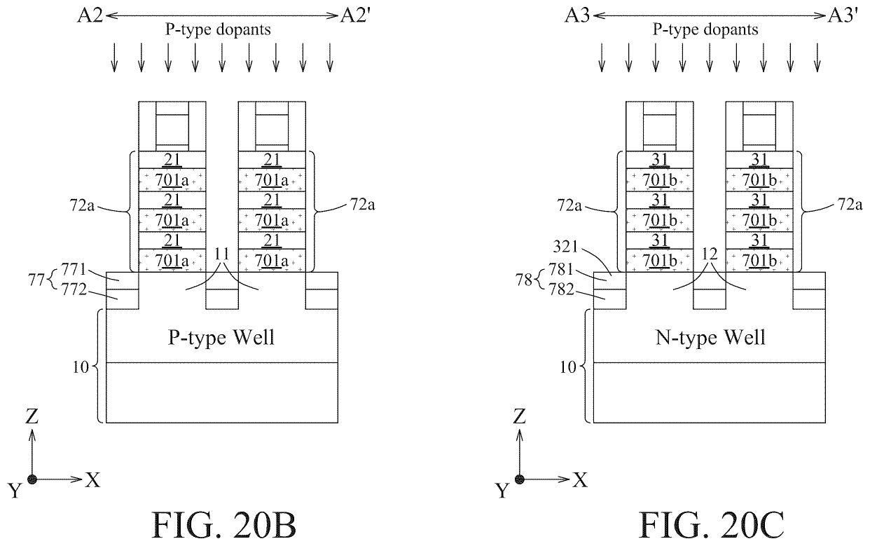

In some embodiments, step S07 may be omitted for manufacturing the second semiconductor structure shown in FIGS. 3A to 3C, and in step S08, the patterned photoresist layer 792 (see FIGS. 13A and 13B) for protecting the structure above the p-type well may be omitted. In such case, in step S08, as shown in FIGS. 20A, 20B and 20C, the upper regions 771, 781 of both the first and second semiconductor portions 77, 78 are doped with the p-type dopants to have a p-type conductivity. The implanted upper region 781 serves as the second doped semiconductor portion 321 of a respective one of the second isolation features 32 (see also FIGS. 3A to 3C). After the thermal treatment performed after formation of the source/drain portions 23, 33, the upper and lower regions 771, 772 of each of the first semiconductor portions 77, the first upper portion of the substrate 10 and the first semiconductor fin 11 together serve as the p-type well.

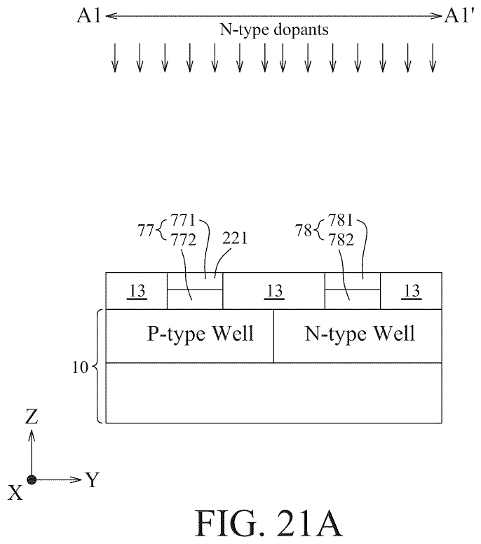

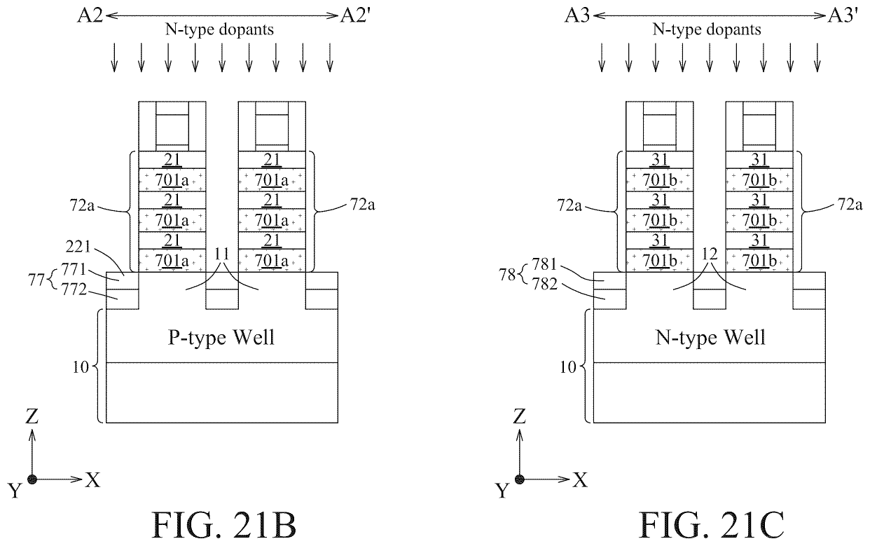

In some embodiments, step S08 may be omitted for manufacturing the third semiconductor structure shown in FIGS. 4A to 4C, and in step S07, the patterned photoresist layer 791 (see FIGS. 12A and 12C) for protecting the structure above the n-type well may be omitted. In such case, in step S07, as shown in FIGS. 21A, 21B and 21C, the upper regions 771, 781 of both the first and second semiconductor portions 77, 78 are doped with the n-type dopants to have an n-type conductivity. The implanted upper region 771 serves as the first doped semiconductor portion 221 of a respective one of the first isolation features 22 (see also FIGS. 4A to 4C). After the thermal treatment performed after formation of the source/drain portions 23, 33, the upper and lower regions 781, 782 of each of the second semiconductor portions 78, the second upper portion of the substrate 10 and the second semiconductor fin 12 together serve as the n-type well.

In summary, each of the n-type and p-type semiconductor devices 101, 102 is provided with bottom dielectric layers (i.e., the first or second insulating portions 222, 322) which are located between the n-type source/drain portions 23 and the p-type well region or between the p-type source/drain portions 33 and the n-type well region so as to block an off-state leakage (Isoff) path and to reduce a capacitance between the source/drain portions 23 or 33 and the gate structures 931, 932 and a capacitance between the n-type or p-type source/drain portions 23 or 33 and the p-type or n-type well region. In addition, at least one of the n-type and p-type semiconductor devices 101, 102 is further provided with doped silicon regions (i.e., the first or second doped semiconductor portions 221, 321) which have a conductivity type same as that of the n-type or p-type source/drain portions 23 or 33 so as to form a p-n junction between the first doped semiconductor portions 221 and the p-type well region or between the second doped semiconductor portions 321 and the n-type well region. In the case that the bottom dielectric layers are undesirably damaged due to high voltage application or poor process control (e.g., the bottom dielectric layers are uneven in thickness with relatively thin region(s), or have defects), the provision of the extra p-n junction located beneath the bottom dielectric layers (i.e., the first and/or second insulating portions 222, 322) can prevent potentially leakage path from being formed between the n-type or p-type source/drain portions 23 or 33 and the p-type or n-type well region. Furthermore, with the provision of the first and/or second isolation features 22, 32 (i.e., the elements 221, 222, 321, 322), the anti-punch through regions APT1, APT2 may be omitted or may be formed with a reduced dosage, and hence the shift of threshold voltage caused by out-diffusion of dopants of the anti-punch through regions APT1, APT2 into the n-channels 21 or the p-channels 31 may be avoided. Therefore, the semiconductor structure may have a reduced current leakage, resulting in better performance.

In accordance with some embodiments of the present disclosure, a semiconductor structure includes: a first well region and a second well region displaced from each other, a conductivity type of the first well region being opposite to a conductivity type of the second well region; a first semiconductor device formed on the first well region and including a first channel, two first source/drain portions which are respectively located at two opposite sides of the first channel, a conductivity type of the two first source/drain portions being opposite to the conductivity type of the first well region, and at least one first isolation feature including a first doped semiconductor portion and a first insulating portion which are respectively in contact with the first well region and a corresponding one of the two first source/drain portions, a conductivity type of the first doped semiconductor portion being the same as the conductivity type of the two first source/drain portions; and a second semiconductor device formed on the second well region and including a second channel, two second source/drain portions which are respectively located at two opposite sides of the second channel, a conductivity type of the two second source/drain portions being opposite to the conductivity type of the second well region, and at least one second isolation feature including a second insulating portion disposed to separate the second well region from a corresponding one of the two second source/drain portions.

In accordance with some embodiments of the present disclosure, a dopant concentration of the first doped semiconductor portion is less than a dopant concentration of each of the two first source/drain portions by at least two to four orders of magnitude.

In accordance with some embodiments of the present disclosure, a difference between a dopant concentration of the first doped semiconductor portion and a dopant concentration of the first well region is not greater than two orders of magnitude.

In accordance with some embodiments of the present disclosure, the second insulating portion is in direct contact with the second well region, a thickness of the second insulating portion being greater than a thickness of the first insulating portion.

In accordance with some embodiments of the present disclosure, a difference between the thickness of the second insulating portion and the thickness of the first insulating portion ranges from 0.5 nm to 3 nm.

In accordance with some embodiments of the present disclosure, the at least one first isolation feature includes two first isolation features. The semiconductor structure further includes a first anti-punch through region formed in the first well region and between the two first isolation features. A conductivity type of the first anti-punch through region is the same as the conductivity type of the first well region. A dopant concentration of the first anti-punch through region is greater than a dopant concentration of the first well region.

In accordance with some embodiments of the present disclosure, a difference between a dopant concentration of the first doped semiconductor portion and a dopant concentration of the first anti-punch through region is less than two orders of magnitude.

In accordance with some embodiments of the present disclosure, the at least one second isolation feature includes two second isolation features. Each of the two second isolation features further includes a second doped semiconductor portion which is disposed to separate the second insulating portion from the second well region. A conductivity type of the second doped semiconductor portion is the same as the conductivity type of the two second source/drain portions.

In accordance with some embodiments of the present disclosure, a dopant concentration of the second doped semiconductor portion is less than a dopant concentration of each of the two second source/drain portions by at least two to four orders of magnitude.

In accordance with some embodiments of the present disclosure, a method for manufacturing a semiconductor structure includes: forming a well region having a first conductivity type; forming a channel; forming two source/drain portions on the well region so that the two source/drain portions are respectively located at two opposite sides of the channel, the two source/drain portions having a second conductivity type which is opposite to the first conductivity type; and forming at least one isolation feature including a doped semiconductor portion and an insulating portion which are respectively in contact with the well region and a corresponding one of the two source/drain portions, the doped semiconductor portion having the second conductivity type.

In accordance with some embodiments of the present disclosure, a dopant concentration of the doped semiconductor portion is less than a dopant concentration of each of the two source/drain portions by at least two to four orders of magnitude.

In accordance with some embodiments of the present disclosure, the insulating portion is formed to be not in physical contact with the channels.

In accordance with some embodiments of the present disclosure, the method further includes: forming a gate dielectric disposed around the channels; forming a gate electrode on the gate dielectric such that the gate electrode is formed around the channels and is separated from the channels through the gate dielectric; forming dielectric units each including two inner spacers, the two inner spacers of each of the dielectric units being respectively formed beneath two end portions of a respective one of the channels so as to separate the two source/drain portions from the gate electrode; forming two contacts respectively on the two source/drain portions; and forming two gate spacers respectively at the two opposite sides of the gate electrode so as to separate the two contacts from the gate electrode. A thickness of each of the two inner spacers being less than a thickness of each of the two gate spacers.

In accordance with some embodiments of the present disclosure, a dielectric constant of the insulating portion is lower than a dielectric constant of the gate dielectric.

In accordance with some embodiments of the present disclosure, the insulating portion includes silicon oxide, silicon oxycarbide, silicon oxynitride, silicon nitride, silicon oxycarbon nitride, or combinations thereof.

In accordance with some embodiments of the present disclosure, the first conductivity type is an n-type conductivity, the second conductivity type is a p-type conductivity, and the doped semiconductor portion includes a group IV semiconductor material which is doped with group III elements.

In accordance with some embodiments of the present disclosure, the first conductivity type is a p-type conductivity, the second conductivity type is an n-type conductivity, and the doped semiconductor portion includes a group IV semiconductor material which is doped with group V elements.

In accordance with some embodiments of the present disclosure, a method for manufacturing a semiconductor structure includes: implanting a substrate with first dopants to form a well region in the substrate, the first dopants having a first conductivity type; forming a patterned structure on the substrate, the patterned structure including channels which are stacked over the substrate and which are spaced apart from each other; etching the well region to form two grooves respectively located two opposite sides of the patterned structure; forming two semiconductor portions respectively in the two grooves; implanting the two semiconductor portions with second dopants, the second dopants having a second conductivity type which is opposite to the first conductivity type; forming two insulating portions respectively on the two semiconductor portions; and forming two source/drain portions respectively on the two insulating portions such that each of the channels extends between the two source/drain portions, the two source/drain portions having the second conductivity type.

In accordance with some embodiments of the present disclosure, the two insulating portions are formed after implantation of the two semiconductor portions.

In accordance with some embodiments of the present disclosure, each of the two semiconductor portions has an upper region and a lower region which are respectively located distal from and proximate to the substrate, and each of the two semiconductor portions is partially implanted during the implantation of the two semiconductor portions such that a dopant concentration of the second dopants at the upper region is greater than a dopant concentration of the second dopants at the lower region.

In accordance with some embodiments of the present disclosure, a method for manufacturing a semiconductor structure includes: forming a first well region and a second well region displaced from each other, a conductivity type of the first well region being opposite to a conductivity type of the second well region; forming a first semiconductor device on the first well region, the first semiconductor device including a first channel, two first source/drain portions which are located at two opposite sides of the first channel, a conductivity type of the two first source/drain portions being opposite to the conductivity type of the first well region, and at least one first isolation feature including a first doped semiconductor portion and a first insulating portion which are respectively in contact with the first well region and a corresponding one of the two first source/drain portions, a conductivity type of the first doped semiconductor portion being the same as the conductivity type of the two first source/drain portions; and forming a second semiconductor device on the second well region, the second semiconductor device including a second channel, two second source/drain portions which are respectively located at two opposite sides of the second channel, a conductivity type of the two second source/drain portions being opposite to the conductivity type of the second well region, and at least one second isolation feature including a second insulating portion disposed to separate the second well region from a corresponding one of the two second source/drain portions.

In accordance with some embodiments of the present disclosure, a dopant concentration of the first doped semiconductor portion is less than a dopant concentration of each of the two first source/drain portions by at least two to four orders of magnitude.

In accordance with some embodiments of the present disclosure, a difference between a dopant concentration of the first doped semiconductor portion and a dopant concentration of the first well region is not greater than two orders of magnitude.

In accordance with some embodiments of the present disclosure, the second insulating portion is formed to be in direct contact with the second well region. A thickness of the second insulating portion being greater than a thickness of the first insulating portion.

In accordance with some embodiments of the present disclosure, a difference between the thickness of the second insulating portion and the thickness of the first insulating portion ranges from 0.5 nm to 3 nm.

In accordance with some embodiments of the present disclosure, the at least one first isolation feature includes two first isolation features. The method further includes forming a first anti-punch through region in the first well region and between the two first isolation features, a conductivity type of the first anti-punch through region being the same as the conductivity type of the first well region, a dopant concentration of the first anti-punch through region being greater than a dopant concentration of the first well region.

In accordance with some embodiments of the present disclosure, a difference between a dopant concentration of the first doped semiconductor portion and a dopant concentration of the first anti-punch through region is less than two orders of magnitude.

In accordance with some embodiments of the present disclosure, the at least one second isolation feature includes two second isolation features. In formation of the second semiconductor device, each of the second isolation features further includes a second doped semiconductor portion which is formed to separate the second insulating portion from the second well region. A conductivity type of the second doped semiconductor portion is the same as the conductivity type of the two second source/drain portions.

In accordance with some embodiments of the present disclosure, a dopant concentration of the second doped semiconductor portion is less than a dopant concentration of each of the two second source/drain portions by at least two to four orders of magnitude.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first well region and a second well region displaced from each other, a conductivity type of the first well region being opposite to a conductivity type of the second well region;
a first semiconductor device formed on the first well region and including
a first channel,
two first source/drain portions which are respectively located at two opposite sides of the first channel, a conductivity type of the two first source/drain portions being opposite to the conductivity type of the first well region, and
at least one first isolation feature including a first doped semiconductor portion and a first insulating portion which are respectively in contact with the first well region and a corresponding one of the two first source/drain portions, a conductivity type of the first doped semiconductor portion being the same as the conductivity type of the two first source/drain portions; and
a second semiconductor device formed on the second well region and including
a second channel,
two second source/drain portions which are respectively located at two opposite sides of the second channel, a conductivity type of the two second source/drain portions being opposite to the conductivity type of the second well region, and
at least one second isolation feature including a second insulating portion disposed to separate the second well region from a corresponding one of the two second source/drain portions.

2. The semiconductor structure as claimed in claim 1, wherein a dopant concentration of the first doped semiconductor portion is less than a dopant concentration of each of the two first source/drain portions by at least two to four orders of magnitude.

3. The semiconductor structure as claimed in claim 1, wherein a difference between a dopant concentration of the first doped semiconductor portion and a dopant concentration of the first well region is not greater than two orders of magnitude.

4. The semiconductor structure as claimed in claim 1, wherein the second insulating portion is in direct contact with the second well region, a thickness of the second insulating portion being greater than a thickness of the first insulating portion.

5. The semiconductor structure as claimed in claim 4, wherein a difference between the thickness of the second insulating portion and the thickness of the first insulating portion ranges from 0.5 nm to 3 nm.

6. The semiconductor structure as claimed in claim 1, wherein the at least one first isolation feature includes two first isolation features, and the semiconductor structure further comprises
a first anti-punch through region formed in the first well region and between the two first isolation features, a conductivity type of the first anti-punch through region being the same as the conductivity type of the first well region, a dopant concentration of the first anti-punch through region being greater than a dopant concentration of the first well region.

7. The semiconductor structure as claimed in claim 6, wherein a difference between a dopant concentration of the first doped semiconductor portion and a dopant concentration of the first anti-punch through region is less than two orders of magnitude.

8. The semiconductor structure as claimed in claim 1, wherein the at least one second isolation feature includes two second isolation features, each of the two second isolation features further including a second doped semiconductor portion which is disposed to separate the second insulating portion from the second well region, a conductivity type of the second doped semiconductor portion being the same as the conductivity type of the two second source/drain portions.

9. The semiconductor structure as claimed in claim 8, wherein a dopant concentration of the second doped semiconductor portion is less than a dopant concentration of each of the two second source/drain portions by at least two to four orders of magnitude.

10. A method for manufacturing a semiconductor structure, comprising:
forming a well region having a first conductivity type;
forming a channel;
forming two source/drain portions on the well region so that the two source/drain portions are respectively located at two opposite sides of the channel, the two source/drain portions having a second conductivity type which is opposite to the first conductivity type; and
forming at least one isolation feature including a doped semiconductor portion and an insulating portion which are respectively in contact with the well region and a corresponding one of the two source/drain portions, the doped semiconductor portion having the second conductivity type.

11. The method as claimed in claim 10, wherein a dopant concentration of the doped semiconductor portion is less than a dopant concentration of each of the two source/drain portions by at least two to four orders of magnitude.

12. The method as claimed in claim 10, wherein the insulating portion is formed to be spaced apart from the channels.

13. The method as claimed in claim 10, further comprising
forming a gate dielectric disposed around the channels;
forming a gate electrode on the gate dielectric such that the gate electrode is formed around the channels and is separated from the channels through the gate dielectric;
forming dielectric units each including two inner spacers, the two inner spacers of each of the dielectric units being respectively formed beneath two end portions of a respective one of the channels so as to separate the two source/drain portions from the gate electrode;
forming two contacts respectively on the two source/drain portions; and
forming two gate spacers respectively at the two opposite sides of the gate electrode so as to separate the two contacts from the gate electrode, a thickness of each of the two inner spacers being less than a thickness of each of the two gate spacers.

14. The semiconductor structure as claimed in claim 13, wherein a dielectric constant of the insulating portion is lower than a dielectric constant of the gate dielectric.

15. The semiconductor structure as claimed in claim 10, wherein the insulating portion includes silicon oxide, silicon oxycarbide, silicon oxynitride, silicon nitride, silicon oxycarbon nitride, or combinations thereof.

16. The semiconductor structure as claimed in claim 10, wherein
the first conductivity type is an n-type conductivity,
the second conductivity type is a p-type conductivity, and
the doped semiconductor portion includes a group IV semiconductor material which is doped with group III elements.

17. The semiconductor structure as claimed in claim 10, wherein
the first conductivity type is a p-type conductivity,
the second conductivity type is an n-type conductivity, and
the doped semiconductor portion includes a group IV semiconductor material which is doped with group V elements.

18. A method for manufacturing a semiconductor structure, comprising:
implanting a substrate with first dopants to form a well region in the substrate, the first dopants having a first conductivity type;
forming a patterned structure on the substrate, the patterned structure including channels which are stacked over the substrate and which are spaced apart from each other;
etching the well region to form two grooves respectively located two opposite sides of the patterned structure;
forming two semiconductor portions respectively in the two grooves;
implanting the two semiconductor portions with second dopants, the second dopants having a second conductivity type which is opposite to the first conductivity type;
forming two insulating portions respectively on the two semiconductor portions; and
forming two source/drain portions respectively on the two insulating portions such that each of the channels extends between the two source/drain portions, the two source/drain portions having the second conductivity type.

19. The method as claimed in claim 18, wherein the two insulating portions are formed after implantation of the two semiconductor portions.

20. The method as claimed in claim 18, wherein
each of the two semiconductor portions has an upper region and a lower region which are respectively located distal from and proximate to the substrate, and
each of the two semiconductor portions is partially implanted during the implantation of the two semiconductor portions such that a dopant concentration of the second dopants at the upper region is greater than a dopant concentration of the second dopants at the lower region.
